(19) United States
(12) Patent Application Publication
(10) Pub. No.: US 2026/0255999 A1
(43) Pub. Date: Aug. 27, 2026

(54) SYSTEMS, METHODS, AND APPARATUS FOR SEMICONDUCTOR PACKAGING WITH SUBSTRATE HAVING THERMALLY CONDUCTIVE LAYER

(71) Applicant: Samsung Electronics Co., Ltd., Suwon-si (KR)

(72) Inventors: Yan LI, Morgan Hill, CA (US); WooPoung KIM, San Jose, CA (US)

(21) Appl. No.: 19/369,177

(22) Filed: Oct. 24, 2025

Related U.S. Application Data
(60) Provisional application No. 63/763,251, filed on Feb. 25, 2025.

(51) Int. Cl. H10W 70/65; H10W 20/42; H10W 20/43; H10W 70/60; H10W 70/63; H10W 90/00

(52) U.S. Cl. CPC H10W 70/65; H10W 20/42; H10W 20/43; H10W 70/611; H10W 70/635; H10W 90/00; H10W 90/701

(57) ABSTRACT

An apparatus may include a device including a first layer having a first thermal conductivity, a second layer having a second thermal conductivity, and a third layer having a third thermal conductivity, wherein the first layer may include a substrate core material, the third layer may include a thermally conductive material, the third thermal conductivity may be greater than the first thermal conductivity, and the third thermal conductivity may be greater than the second thermal conductivity. The third layer may be located between the first layer and the second layer. The second layer may include a substrate core material. The second layer may include a semiconductor die. The second layer may include an energy storage device. The second layer may include a power delivery network. The apparatus may further include a fourth layer attached to the first layer, wherein the fourth layer may include a lamination layer.

### REFERENCE TO RELATED APPLICATION

This application claims priority to, and the benefit of, U.S. Provisional Patent Application Serial No. 63/763,251 filed February 25, 2025 which is incorporated by reference.

### TECHNICAL FIELD

This disclosure relates generally to semiconductor packaging, and more specifically to systems, methods, and apparatus for semiconductor packaging with a substrate having a thermally conductive layer.

### BACKGROUND

Some semiconductor packaging techniques may combine multiple integrated circuit dies in a package. For example, different types of integrated circuits such as memory devices, processing devices, and/or the like, may be fabricated on separate semiconductor dies using different processes. The dies may be physically and/or electrically connected to one or more substrates and enclosed in a package to provide physical, thermal, and/or electrical protection.

The above information disclosed in this Background section is only for enhancement of understanding of the background of the inventive principles and therefore it may contain information that does not constitute prior art.

### SUMMARY

An apparatus may include a device including a first layer having a first thermal conductivity, a second layer having a second thermal conductivity, and a third layer having a third thermal conductivity, wherein the first layer may include a substrate core material, the third layer may include a thermally conductive material, the third thermal conductivity may be greater than the first thermal conductivity, and the third thermal conductivity may be greater than the second thermal conductivity. The third layer may be located between the first layer and the second layer. The second layer may include a substrate core material. The second layer may include a semiconductor die. The second layer may include an energy storage device. The second layer may include a power delivery network. The apparatus may further include a fourth layer attached to the first layer, wherein the fourth layer may include a lamination layer. The apparatus may further include a fourth layer attached to the first layer, wherein the fourth layer may include a distribution layer. The device may be a first substrate core structure, and the apparatus may further include a second substrate core structure attached to the first substrate core structure. The first layer may be bonded to the third layer.

An apparatus may include a substrate including first core portion including a first layer having a first thermal conductivity, wherein the first layer may include a substrate core material, and a second layer having a second thermal conductivity, wherein the second layer may include a thermally conductive material, a second core portion including a third layer having a third thermal conductivity, wherein the first layer may include a substrate core material, and a fourth layer having a fourth thermal conductivity, wherein the fourth layer may include a thermally conductive material, and a lamination layer attached to the first core portion and the second core portion, wherein the second thermal conductivity may be greater than the first thermal conductivity, and wherein the fourth thermal conductivity may be greater than the third thermal conductivity. The substrate may include a via between the first core portion and the second core portion, wherein the via may be connected to the lamination layer. The lamination layer may include a via connected to the first core portion. The apparatus may further include a semiconductor die structure attached to the lamination layer. The first layer may be attached to a first side of the second layer, the first core portion may further include a fifth layer attached to a second side of the second layer, and the fifth layer may include a substrate core material. The apparatus may further include a first semiconductor die structure attached to the lamination layer, and a second semiconductor die structure attached to the lamination layer, wherein the first core portion further may include a semiconductor die layer attached to the second layer and electrically connected to the first semiconductor die structure and the second semiconductor die structure. The substrate may be a first substrate, and the apparatus may further include a second substrate attached to the first substrate.

A method may include performing, on a substrate core layer, a thinning operation, thereby forming a modified substrate core layer, and attaching, to the modified substrate core layer, a thermally conductive layer, thereby forming a substrate core structure, wherein the thermally conductive layer has a thermal conductivity that may be greater than a thermal conductivity of the modified substrate core layer. The method may further include attaching, to the modified substrate core layer, a lamination layer. The modified substrate core layer may be attached to a first side of the thermally conductive layer, and the method may further include attaching, to a second side of the thermally conductive layer, a semiconductor die layer.

### BRIEF DESCRIPTION OF THE DRAWINGS

The figures are not necessarily drawn to scale and elements of similar structures or functions or portions thereof may generally be represented by reference indicators ending in, and/or containing, the same digits, letters, and/or the like, for illustrative purposes throughout the figures. The figures are only intended to facilitate the description of the various embodiments described herein. The figures do not describe every aspect of the teachings disclosed herein and do not limit the scope of the claims. To prevent the drawings from becoming obscured, not all of the components, connections, and the like, may be shown, and not all of the components may have reference numbers. However, patterns of component configurations may be readily apparent from the drawings. The accompanying drawings, together with the specification, illustrate example embodiments of the present disclosure, and, together with the description, serve to explain the principles of the present disclosure.

FIG. 1 illustrates a cross-sectional view of an embodiment of a substrate structure in accordance with example embodiments of the disclosure.

FIG. 2 illustrates a cross-sectional view of an embodiment of a substrate core structure having two substrate core layers in accordance with example embodiments of the disclosure.

FIG. 3 illustrates a cross-sectional view of an embodiment of a substrate core structure having a semiconductor die layer and a substrate core layer in accordance with example embodiments of the disclosure.

FIG. 4 illustrates a cross-sectional view of an embodiment of a substrate core structure having an energy storage layer and a substrate core layer in accordance with example embodiments of the disclosure.

FIG. 5A illustrates a cross-sectional view of an embodiment of a semiconductor die having an active layer in accordance with example embodiments of the disclosure.

FIG. 5B illustrates a cross-sectional view of an embodiment of a semiconductor die with semiconductor material removed in accordance with example embodiments of the disclosure.

FIG. 5C illustrates a cross-sectional view of an embodiment of a structure having a thinned semiconductor die attached to a thermally conductive layer in accordance with example embodiments of the disclosure.

FIG. 6A illustrates a cross-sectional view of an embodiment of a substrate core layer in accordance with example embodiments of the disclosure.

FIG. 6B illustrates a cross-sectional view of an embodiment of a substrate core layer with core material removed in accordance with example embodiments of the disclosure.

FIG. 6C illustrates a cross-sectional view of an embodiment of a substrate core structure having a thinned substrate core layer attached to a thermally conductive layer in accordance with example embodiments of the disclosure.

FIG. 7 illustrates a cross-sectional view of the embodiment of a substrate structure having substrate core portions including substrate core layers in accordance with example embodiments of the disclosure.

FIG. 8 illustrates a cross-sectional view of the embodiment of a substrate structure having substrate core portions including at least one substrate core layer and one or more semiconductor die layers in accordance with example embodiments of the disclosure.

FIG. 9 illustrates a cross-sectional view of an embodiment of a package architecture having a substrate structure with stacked core layers and one or more dies attached to the substrate structure in accordance with example embodiments of the disclosure.

FIG. 10 illustrates a cross-sectional view of an embodiment of a package architecture having a substrate with stacked core layers with one or more semiconductor die layers and one or more dies attached to the substrate in accordance with example embodiments of the disclosure.

FIG. 11 illustrates a cross-sectional view of an embodiment of a package architecture having a substrate with stacked core layers with substrate core layers and one or more dies attached to the substrate in accordance with example embodiments of the disclosure.

FIG. 12 illustrates a cross-sectional view of an embodiment of a package architecture having a substrate with stacked core layers with one or more semiconductor die layers and one or more dies attached to two sides of the substrate in accordance with example embodiments of the disclosure.

FIG. 13 illustrates a cross-sectional view of an embodiment of a package architecture having two stacked substrates with stacked core layers having one or more semiconductor die layers and one or more dies attached to two sides of the stacked substrates in accordance with example embodiments of the disclosure.

FIG. 14 illustrates a cross-sectional view of an embodiment of a package architecture having two or more stacked substrates with stacked core layers having one or more semiconductor die layers in accordance with example embodiments of the disclosure.

FIG. 15A illustrates a cross-sectional view of an embodiment of a package architecture having at least one substrate with one or more portions having stacked core layers with one or more semiconductor die layers and one or more semiconductor dies attached to the substrate, wherein at least one of the semiconductor die layers and/or semiconductor dies includes a backside power distribution network in accordance with example embodiments of the disclosure.

FIG. 15B illustrates an enlarged cross-sectional view of a portion of the semiconductor die illustrated in FIG. 15A.

FIG. 16A illustrates a cross-sectional view of an embodiment of a package architecture having at least one substrate with one or more portions having stacked core layers with one or more semiconductor die layers and one or more semiconductor dies attached to the substrate, wherein at least one of the semiconductor die layers and/or semiconductor dies includes a backside power distribution network and/or a second semiconductor die layer in accordance with example embodiments of the disclosure.

FIG. 16B illustrates an enlarged cross-sectional view of a portion of the semiconductor die structure illustrated in FIG. 16A.

FIG. 17A illustrates a cross-sectional view of an embodiment of an operation for attaching a substrate core layer to a carrier for a substrate core structure including one or more substrate core portions having substrate core layers attached to a thermally conductive layer, and a method of fabrication thereof, in accordance with example embodiments of the disclosure.

FIG. 17B illustrates a cross-sectional view of an embodiment of an operation for thinning a substrate layer for a substrate core structure including one or more substrate core portions having substrate core layers attached to a thermally conductive layer, and a method of fabrication thereof, in accordance with example embodiments of the disclosure.

FIG. 17C illustrates a cross-sectional view of an embodiment of an operation for attaching a thermally conductive layer to a substrate core layer for a substrate core structure including one or more substrate core portions having substrate core layers attached to a thermally conductive layer, and a method of fabrication thereof, in accordance with example embodiments of the disclosure.

FIG. 17D illustrates a cross-sectional view of an embodiment of an operation for attaching a second substrate core layer and a second carrier to a thermally conductive layer for a substrate core structure including one or more substrate core portions having substrate core layers attached to a thermally conductive layer, and a method of fabrication thereof, in accordance with example embodiments of the disclosure.

FIG. 17E illustrates a cross-sectional view of an embodiment of an operation for singulating assemblies having a thermally conductive layer attached to a substrate core layer for a substrate core structure including one or more substrate core portions having substrate core layers attached to a thermally conductive layer, and a method of fabrication thereof, in accordance with example embodiments of the disclosure.

FIG. 17F illustrates a cross-sectional view of an embodiment of assemblies having substrate core layers attached to a thermally conductive layer in accordance with example embodiments of the disclosure.

FIG. 18A illustrates a cross-sectional view of an embodiment of an operation for attaching a substrate core layer to a carrier for a substrate core structure including one or more substrate core portions having a substrate core layer attached to a first side of a thermally conductive layer and a semiconductor die layer attached to a second side of the thermally conductive layer, and a method of fabrication thereof, in accordance with example embodiments of the disclosure.

FIG. 18B illustrates a cross-sectional view of an embodiment of an operation for thinning a substrate layer for a substrate core structure including one or more substrate core portions having a substrate core layer attached to a first side of a thermally conductive layer and a semiconductor die layer attached to a second side of the thermally conductive layer, and a method of fabrication thereof, in accordance with example embodiments of the disclosure.

FIG. 18C illustrates a cross-sectional view of an embodiment of an operation for attaching a thermally conductive layer to a substrate core layer for a substrate core structure including one or more substrate core portions having a substrate core layer attached to a first side of a thermally conductive layer and a semiconductor die layer attached to a second side of the thermally conductive layer, and a method of fabrication thereof, in accordance with example embodiments of the disclosure.

FIG. 18D illustrates a cross-sectional view of an embodiment of an operation for attaching a semiconductor die layer and a second carrier to a thermally conductive layer for a substrate core structure including one or more substrate core portions having a substrate core layer attached to a first side of a thermally conductive layer and a semiconductor die layer attached to a second side of the thermally conductive layer, and a method of fabrication thereof, in accordance with example embodiments of the disclosure.

FIG. 18E illustrates a cross-sectional view of an embodiment of an operation for singulating assemblies having a thermally conductive layer attached to a substrate core layer and a semiconductor die layer for a substrate core structure including one or more substrate core portions having a substrate core layer attached to a first side of a thermally conductive layer and a semiconductor die layer attached to a second side of the thermally conductive layer, and a method of fabrication thereof, in accordance with example embodiments of the disclosure.

FIG. 18F illustrates a cross-sectional view of an embodiment of assemblies having a substrate core layer attached to a first side of a thermally conductive layer and a semiconductor die layer attached to a second side of the thermally conductive layer in accordance with example embodiments of the disclosure.

FIG. 19A illustrates a cross-sectional view of an embodiment of a method for attaching a semiconductor die layer to a carrier in accordance with example embodiments of the disclosure.

FIG. 19B illustrates a cross-sectional view of an embodiment of a method for thinning a semiconductor die layer in accordance with example embodiments of the disclosure.

FIG. 20A illustrates a cross-sectional view of an embodiment of an operation for attaching a substrate core layer to a carrier for a substrate core structure including one or more substrate core portions having a substrate core layer attached to a first side of a thermally conductive layer and a semiconductor die layer attached to a second side of the thermally conductive layer, and a method of fabrication with a known good die thereof, in accordance with example embodiments of the disclosure.

FIG. 20B illustrates a cross-sectional view of an embodiment of an operation for thinning a substrate layer for a substrate core structure including one or more substrate core portions having a substrate core layer attached to a first side of a thermally conductive layer and a semiconductor die layer attached to a second side of the thermally conductive layer, and a method of fabrication with a known good die thereof, in accordance with example embodiments of the disclosure.

FIG. 20C illustrates a cross-sectional view of an embodiment of an operation for attaching a thermally conductive layer to a substrate core layer for a substrate core structure including one or more substrate core portions having a substrate core layer attached to a first side of a thermally conductive layer and a semiconductor die layer attached to a second side of the thermally conductive layer, and a method of fabrication with a known good die thereof, in accordance with example embodiments of the disclosure.

FIG. 20D illustrates a cross-sectional view of an embodiment of an operation for singulating assemblies having a thermally conductive layer attached to a substrate core layer for a substrate core structure including one or more substrate core portions having a substrate core layer attached to a first side of a thermally conductive layer and a semiconductor die layer attached to a second side of the thermally conductive layer, and a method of fabrication with a known good die thereof, in accordance with example embodiments of the disclosure.

FIG. 20E illustrates a cross-sectional view of an embodiment of singulated assemblies having a thermally conductive layer attached to a substrate core layer in accordance with example embodiments of the disclosure.

FIG. 20F illustrates a cross-sectional view of an embodiment of an operation for attaching one or more singulated assemblies having a substrate core layer and a thermally conductive layer to one or more known good dies of a semiconductor die layer attached to a second carrier in accordance with example embodiments of the disclosure.

FIG. 20G illustrates a cross-sectional view of an embodiment of an operation for singulating assemblies having a thermally conductive layer attached to a substrate core layer and a semiconductor die layer for a substrate core structure including one or more substrate core portions having a substrate core layer attached to a first side of a thermally conductive layer and a semiconductor die layer attached to a second side of the thermally conductive layer, and a method of fabrication with a known good die thereof, in accordance with example embodiments of the disclosure.

FIG. 20H illustrates a cross-sectional view of an embodiment of assemblies having a substrate core layer attached to a first side of a thermally conductive layer and a semiconductor die layer attached to a second side of the thermally conductive layer in accordance with example embodiments of the disclosure.

FIG. 21A illustrates a cross-sectional view of an embodiment of an operation for attaching one or more substrate core portions to a carrier for a method for fabricating a substrate structure having a substrate core structure with one or more portions having a thermally conductive layer stacked between layers of substrate core materials, and an assembly fabricated thereby, in accordance with example embodiments of the disclosure.

FIG. 21B illustrates a cross-sectional view of an embodiment of an operation for attaching a lamination layer to one or more substrate core portions for a method for fabricating a substrate structure having a substrate core structure with one or more portions having a thermally conductive layer stacked between layers of substrate core materials, and an assembly fabricated thereby, in accordance with example embodiments of the disclosure.

FIG. 21C illustrates a cross-sectional view of an embodiment of an operation for attaching a second carrier to one or more substrate core portions for a method for fabricating a substrate structure having a substrate core structure with one or more portions having a thermally conductive layer stacked between layers of substrate core materials, and an assembly fabricated thereby, in accordance with example embodiments of the disclosure.

FIG. 21D illustrates a cross-sectional view of an embodiment of an operation for removing a die attach film from one or more substrate core portions for a method for fabricating a substrate structure having a substrate core structure with one or more portions having a thermally conductive layer stacked between layers of substrate core materials, and an assembly fabricated thereby, in accordance with example embodiments of the disclosure.

FIG. 21E illustrates a cross-sectional view of an embodiment of an operation for attaching a second lamination layer to one or more substrate core portions for a method for fabricating a substrate structure having a substrate core structure with one or more portions having a thermally conductive layer stacked between layers of substrate core materials, and an assembly fabricated thereby, in accordance with example embodiments of the disclosure.

FIG. 21F illustrates a cross-sectional view of an embodiment of an operation for forming one or more vias in a lamination layer and/or gap filling material for a method for fabricating a substrate structure having a substrate core structure with one or more portions having a thermally conductive layer stacked between layers of substrate core materials, and an assembly fabricated thereby, in accordance with example embodiments of the disclosure.

FIG. 21G illustrates a cross-sectional view of an embodiment of an operation for filling one or more vias in a lamination layer and/or gap filling material with conductive material for a method for fabricating a substrate structure having a substrate core structure with one or more portions having a thermally conductive layer stacked between layers of substrate core materials, and an assembly fabricated thereby, in accordance with example embodiments of the disclosure.

FIG. 21H illustrates a cross-sectional view of an embodiment of an operation for forming one or more redistribution layers on one or more portions of a substrate core structure having a thermally conductive layer stacked between layers of substrate core materials, and an assembly fabricated thereby, in accordance with example embodiments of the disclosure.

FIG. 22A illustrates a cross-sectional view of an embodiment of an operation for attaching one or more substrate core portions to a carrier for a method for fabricating a substrate structure having a substrate core structure with one or more portions having a thermally conductive layer stacked between a layer of substrate core material and a semiconductor die layer, and an assembly fabricated thereby, in accordance with example embodiments of the disclosure.

FIG. 22B illustrates a cross-sectional view of an embodiment of an operation for attaching a lamination layer to one or more substrate core portions for a method for fabricating a substrate structure having a substrate core structure with one or more portions having a thermally conductive layer stacked between a layer of substrate core material and a semiconductor die layer, and an assembly fabricated thereby, in accordance with example embodiments of the disclosure.

FIG. 22C illustrates a cross-sectional view of an embodiment of an operation for attaching a second carrier to one or more substrate core portions for a method for fabricating a substrate structure having a substrate core structure with one or more portions having a thermally conductive layer stacked between a layer of substrate core material and a semiconductor die layer, and an assembly fabricated thereby, in accordance with example embodiments of the disclosure.

FIG. 22D illustrates a cross-sectional view of an embodiment of an operation for removing a die attach film from one or more substrate core portions for a method for fabricating a substrate structure having a substrate core structure with one or more portions having a thermally conductive layer stacked between a layer of substrate core material and a semiconductor die layer, and an assembly fabricated thereby, in accordance with example embodiments of the disclosure.

FIG. 22E illustrates a cross-sectional view of an embodiment of an operation for attaching a second lamination layer to one or more substrate core portions for a method for fabricating a substrate structure having a substrate core structure with one or more portions having a thermally conductive layer stacked between a layer of substrate core material and a semiconductor die layer, and an assembly fabricated thereby, in accordance with example embodiments of the disclosure.

FIG. 22F illustrates a cross-sectional view of an embodiment of an operation for forming one or more vias in a lamination layer and/or gap filling material for a method for fabricating a substrate structure having a substrate core structure with one or more portions having a thermally conductive layer stacked between a layer of substrate core material and a semiconductor die layer, and an assembly fabricated thereby, in accordance with example embodiments of the disclosure.

FIG. 22G illustrates a cross-sectional view of an embodiment of an operation for filling one or more vias in a lamination layer and/or gap filling material with conductive material for a method for fabricating a substrate structure having a substrate core structure with one or more portions having a thermally conductive layer stacked between a layer of substrate core material and a semiconductor die layer, and an assembly fabricated thereby, in accordance with example embodiments of the disclosure.

FIG. 22H illustrates a cross-sectional view of an embodiment of an operation for forming one or more redistribution layers on one or more portions of a substrate core structure having a thermally conductive layer stacked between a layer of substrate core material and a semiconductor die layer, and an assembly fabricated thereby, in accordance with example embodiments of the disclosure.

### DETAILED DESCRIPTION

A semiconductor package may include a substrate having one or more components attached to a surface of the substrate. Some substrates may include one or more core materials such as a semiconductor (e.g., silicon) or glass which may have better mechanical and/or electrical properties than organic core materials, and therefore, may enable the fabrication of larger and/or higher performance substrates and/or packages. For example, the rigidness of semiconductor and/or glass core materials may enable the fabrication of larger substrates that may enable more and/or larger semiconductor dies to be attached to the substrate.

However, increasing the number, size, and/or performance of semiconductor dies attached to a substrate may make it difficult to control the flow of heat within, and/or from, the substrate and/or one or more semiconductor dies attached to, and/or embedded in, the substrate. For example, an active semiconductor die may develop hot spots that may damage the die or cause it to shut down. Removing heat from hot spots may be difficult because the heat may need to travel through the semiconductor die, the substrate, and/or any additional layers attached to the substrate. It may be especially difficult to control the flow of heat within and/or from a semiconductor die that has a backside power delivery network (BSPDN) because such a die may have a relatively high power density.

Some aspects of the disclosure relate to the use of one or more thermally conductive layers to spread heat within, and/or remove heat from, a substrate and/or one or more semiconductor dies attached to, and/or embedded within, a substrate. For example, in some embodiments, a substrate may include a thermally conductive layer having a relatively high thermal conductivity attached to a layer of substrate core material having a relatively low thermal conductivity. In some embodiments, layers of one or more substrate core materials having relatively low thermal conductivities may be attached to two sides of a thermally conductive layer having a relatively high thermal conductivity.

Depending on the implementation details, a thermally conductive layer attached to one or more layers of substrate core materials may spread heat within the substrate, thereby reducing the temperature of one or more hot spots within the substrate and/or within a semiconductor die attached to, or embedded in, the substrate. Additionally, or alternatively, depending on the implementation details, this may enable the utilization of existing substrate core processes for semiconductor, glass, and/or the like, to fabricate substrates having improved thermal management. Additionally, or alternatively, depending on the implementation details, this may enable the utilization of existing die embedding and/or stacking processes to fabricate stacks of one or more layers of substrate core materials with a thermally conductive layer. Additionally, or alternatively, depending on the implementation details, this may enable a thickness of the thermally conductive layer to be reduced, thereby reducing costs, possibly without reducing performance.

In some embodiments, a core structure (e.g., a stack) having a layer of substrate core material attached to a first side of a thermally conductive layer may have a semiconductor die, an energy storage device, and/or any other device or material attached to a second side of the thermally conductive layer. For example, in some embodiments, a core structure may include a layer of substrate core material attached to a first side of a thermally conductive layer and an active semiconductor die attached to a second side of the thermally conductive layer. The active semiconductor die may be implemented, for example, as a bridge (e.g., to connect two or more semiconductor dies attached to a surface of the substrate), a memory, a processing circuit, and/or the like. Depending on the implementation details, this may result in a relatively rigid substrate structure while enabling the thermally conductive layer to spread and/or remove heat from one or more hot spots in the semiconductor die and/or other locations within the substrate.

As another example, in some embodiments, a core structure may include a layer of substrate core material attached to a first side of a thermally conductive layer and an integrated stacked capacitor (ISC) attached to a second side of the thermally conductive layer. Depending on the implementation details, this may enable the ISC to be located relatively close to one or more semiconductor dies, thereby improving power delivery performance.

Some additional aspects of the disclosure relate to substrates having two or more portions (e.g., two or more stacks) formed from a thermally conductive layer stacked with at least one layer of substrate core material. In some embodiments, one or more lamination processes may be used to fill one or more gaps between the two or more portions and/or to form a layer on one or more sides of the substrate. Depending on the implementation details, this may enable distribution layers on two sides of the substrate, and/or one or more semiconductor dies attached to, or embedded in, the substrate, to communicate through one or more vias in one or more gaps between portions of the substrate.

Some additional aspects of the disclosure relate to substrates in which a thermally conductive layer may be located relatively close to an active layer of a semiconductor die and/or any other device that may be embedded in, and/or attached to, the substrate. For example, a thinning process may be used to remove semiconductor material from a semiconductor die to form a surface that is relatively close to an active (e.g., transistor) layer of the die. The surface of the semiconductor die (which may have a relatively low thermal conductivity) may be attached to a first side of a thermally conductive layer having a relatively high thermal conductivity. A substrate core layer may be attached to a second side of the thermally conductive layer. Depending on the implementation details, this may result in a relatively rigid substrate structure that may efficiently spread heat within, and/or remove heat from, one or more hot spots in the semiconductor die and/or other locations within the substrate, and/or one or more devices that may be attached to the substrate.

Additionally, or alternatively, a thinning process may be used to remove material from one or more substrate core materials attached to one or two sides of a thermally conductive layer. For example, a wafer of substrate core material (e.g., a semiconductor and/or glass) may be attached to a carrier and thinned to a specified thickness. The thinned substrate core material may be attached to a first side of a thermally conductive layer to form a first substrate core layer. In some embodiments, a second wafer of substrate core material may be attached to a second carrier and thinned to a specified thickness. The second thinned substrate core material may be attached to a second side of a thermally conductive layer to form a second substrate core layer. Depending on the implementation details, this may result in a relatively rigid substrate structure having a thermally conductive layer relatively close to one or more semiconductor dies and/or other devices attached to the substrate, thereby efficiently spreading heat within, and/or removing heat from, one or more hot spots in the one or more semiconductor dies and/or other devices attached to the substrate.

One or more aspects of the disclosure may be especially useful for controlling the flow of heat within and/or from semiconductor dies having power delivery networks. For example, a semiconductor die having a power delivery network (e.g., a BSPDN) may include a power delivery network located near one surface of the die, a signal network near another surface of the die, and an active layer located between the power delivery network and the signal network. An embodiment in accordance with the disclosure may include a thermally conductive layer having a first side attached to a surface of the die near the signal network. Additionally, or alternatively, a thermally conductive layer may have a first side attached to a surface of the die near the power delivery network. In some embodiments, a layer of substrate core material may be attached to a second side of the thermally conductive layer, thereby forming a stacked substrate structure. Depending on the implementation details, this may spread heat from one or more hot spots within the die, and/or remove heat from the die and/or one or more hot spots, thereby reducing the temperature of the die and/or one or more hot spots within the die. Moreover, a thermally conductive layer in such a stacked substrate structure may spread heat from one or more hot spots within a die attached to the layer of substrate core material, and/or remove heat from the die and/or one or more hot spots, thereby reducing the temperature of the die and/or one or more hot spots within the die.

In some embodiments, and depending on the implementation details, techniques disclosed herein may enable configurations of substrates and/or dies having relatively high circuitry and/or power densities to be attached to, and/or embedded in, substrates. Additionally, or alternatively, these techniques may enable relatively dense configurations of other components such as ISCs to be attached to, and/or embedded in, substrates which, depending on the implementation details, may improve the performance of power delivery networks.

This disclosure encompasses numerous aspects relating to semiconductor packaging. The aspects disclosed herein may have independent utility and may be embodied individually, and not every embodiment may utilize every aspect. Moreover, the aspects may also be embodied in various combinations, some of which may amplify some benefits of the individual aspects in a synergistic manner.

For purposes of illustration, some embodiments may be described in the context of some specific implementation details such as semiconductor die types, attachment (e.g., bonding) techniques, types of thermally conductive layers, and/or the like. However, the aspects of the disclosure are not limited to these or any other implementation details. For example, some embodiments may be described as having substrate core layers attached to two sides of a thermally conductive layer, but some embodiments may be fabricated in the same or a similar manner with a substrate core layer attached to one side (e.g., only one side) of a thermally conductive layer.

In some embodiments, a thermally conductive layer may refer to a layer having a thermal conductivity greater than one or more substrate core layers, semiconductor dies, energy storage devices, and/or the like, to which it may be attached. In some embodiments, a die may refer to a semiconductor die.

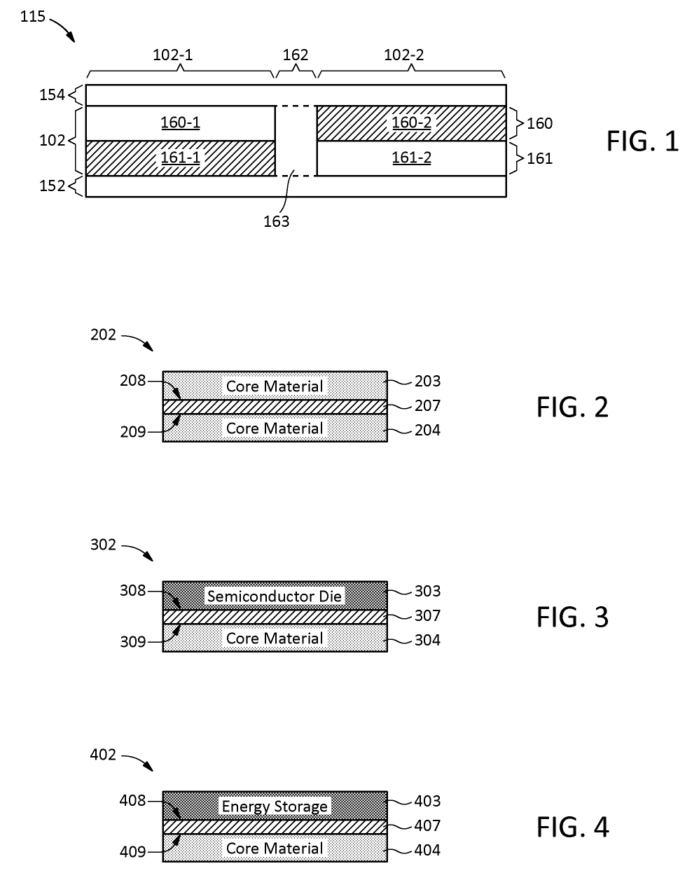

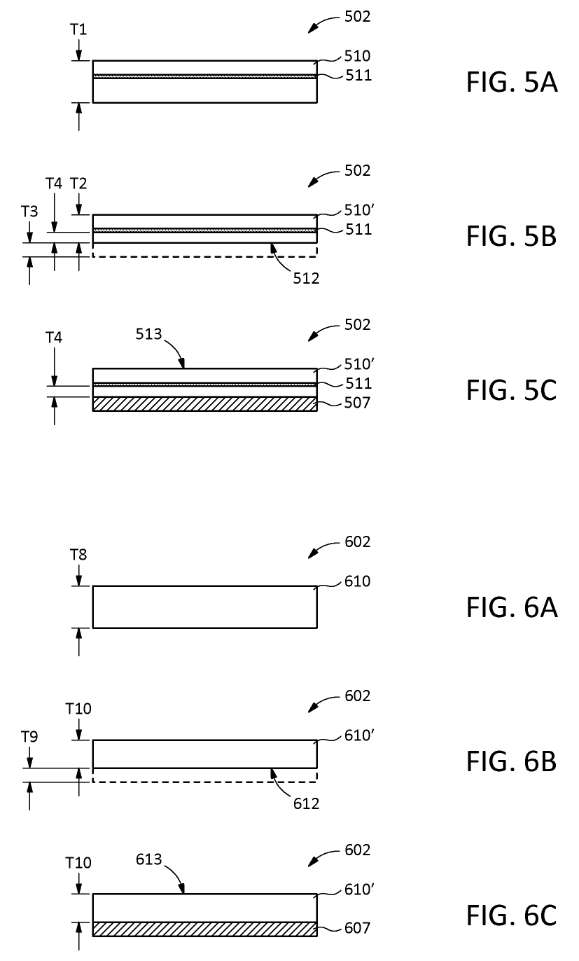

In some example embodiments described here, reference indicators having a base portion and a suffix portion may be referred to collectively and/or individually by the base portion. For example, portions 102-1 and/or 102-2 of core structure 102 illustrated in FIG. 1 may be referred to collectively and/or individually as 102. Multiple figures having the same numbers with different letter suffixes may be referred to collectively and/or individually by the number. For Example, FIGS. 5A through 5C may be referred to collectively and/or individually as FIG. 5.

FIG. 1 illustrates a cross-sectional view of an embodiment of a substrate structure in accordance with example embodiments of the disclosure. The substrate structure 115 illustrated in FIG. 1 may include a core structure 102 having a first layer 160 and a second layer 161. Core structure 102 may include a first portion 102-1 and a second portion 102-2. First portion 102-1 of core structure 102 may include a first portion 160-1 of first layer 160 and a first portion 161-1 of second layer 161. First portion 102-2 of core structure 102 may include a second portion 160-2 of first layer 160 and a second portion 161-2 of second layer 161.

First layer 160 and/or second layer 161 may include one or more substrate core materials, thermally conductive materials, and/or combinations thereof. For purposes of illustration, in the embodiment illustrated in FIG. 1, first portion of first layer 160-1 may be implemented with one or more substrate core materials, first portion of second layer 161-1 may be implemented with one or more thermally conductive materials, second portion of first layer 160-2 may be implemented with one or more thermally conductive materials, and second portion of second layer 161-2 may be implemented with one or more substrate core materials. In other embodiments, however, any other arrangement of core materials and/or thermally conductive materials may be used.

For purposes of illustration, in the embodiment illustrated in FIG. 1, a layer implemented with one or more thermally conductive materials may have a thermal conductivity greater than a thermal conductivity of a layer implemented with one or more substrate core materials. Depending on the implementation details, this may enable a thermally conductive layer to redistribute (e.g., spread) heat within, and/or remove heat from, a substrate and/or one or more semiconductor dies and/or other devices attached to, and/or embedded within, a substrate.

For purposes of illustration, in the embodiment illustrated in FIG. 1, core structure 102 may include first portion 102-1 and second portion 102-2, but in other embodiments, core structure 102 may include any number of portions. Additionally, or alternatively, in other embodiments, core structure 102 and/or one or more portions thereof may include one or more additional layers. For example, in some embodiments, first portion 102-1 of core structure 102 may include a third layer implemented with substrate core material such that thermally conductive layer 161-1 may be stacked between two layers of substrate core materials. As another example, in some embodiments, first portion 102-1 of core structure 102 may include a third layer implemented with thermally conductive material such that substrate core layer 160-1 may be stacked between two layers of thermally conductive materials. As a further example, first portion 102-1 of core structure 102 may include a third layer implemented with a semiconductor die (e.g., an active semiconductor die), an energy storage device (e.g., an ISC), and/or the like.

Examples of substrate core materials that may be used in any embodiments disclosed herein may include one or more organic materials, semiconductors (e.g., silicon, gallium arsenide (GaAs), silicon carbide (SiC), silicon nitride (SiN), and/or the like), glass materials, and/or the like, or a combination thereof.

Examples of thermally conductive materials that may be used in any embodiments disclosed herein may include single crystal diamond (SCD), polycrystalline diamond (PCD), amorphous diamond (AD), diamond-like carbon (DLC), boron arsenide, and/or the like, or a combination thereof. Other examples may include any type of material that may have a relatively wide bandgap (so it has relatively low electrical conductivity) while also having a relatively high thermal conductivity. Examples of other materials having a relatively wide bandgap and relatively high thermal conductivity may include aluminum nitride (AlN), silicon carbide (SiC), and/or the like. In some embodiments, a thermally conductive material may spread, remove, and/or transfer heat as described herein. In some embodiments, a thermally conductive material may have a higher thermal conductivity than one or more adjacent materials, structures, and/or the like, such as substrate core materials, semiconductor dies, energy storage devices, and/or the like.

Substrate structure 115 may also include a first lamination layer 152 and/or a second lamination layer 154. In some embodiments, first lamination layer 152 and/or second lamination layer 154 may provide one or more mechanical, thermal, and/or electrical properties to substrate structure 115. For example, first lamination layer 152 and/or second lamination layer 154 may provide mechanical support to first portion 102-1 and/or second portion 102-2 of core structure 102 which, depending on the implementation details, may result in a relatively rigid substrate structure 115. As another example, in some embodiments, first lamination layer 152 and/or second lamination layer 154 may form all or part of a redistribution layer to provide one or more electrical connections to first portion 102-1 and/or second portion 102-2 of core structure 102, one or more semiconductor dies and/or other devices attached to one or more sides of substrate structure 115, and/or the like.

Examples of materials that may be used to implement first lamination layer 152 and/or second lamination layer 154, as well as in any other embodiments disclosed herein, may include build up film, redistribution layer (RDL) dry film, and/or the like.

In some embodiments, substrate structure 115 may include one or more gaps 162 between one or more portions of core structure 102. In some embodiments, one or more gaps 162 may be at least partially filled with a gap filling material 163. Gap filling material 163 may be formed, for example, as part of first lamination layer 152 and/or second lamination layer 154. In some embodiments, one or more vias may be formed in gap filling material 163, for example, to provide one or more electrical connections between one or more RDLs formed with first lamination layer 152 and/or second lamination layer 154, one or more portions of core structure 102, one or more semiconductor dies and/or other devices attached to one or more sides of substrate structure 115, and/or the like. Substrate structure 115 may be fabricated, for example, using one or more wafer scale operations, one or more panel scale operations, and/or the like.

FIG. 2 illustrates a cross-sectional view of an embodiment of a substrate core structure having two substrate core layers in accordance with example embodiments of the disclosure. The core structure 202 illustrated in FIG. 2 may include a first layer of substrate core material 203 having a first thermal conductivity, a second layer of substrate core material 204 having a second thermal conductivity, and a thermally conductive layer 207 having a third thermal conductivity. Thermally conductive layer 207 may have a first side 208 attached to first semiconductor die 203 and a second side 209 attached to second semiconductor die 204. The third thermal conductivity of the thermally conductive layer 207 may be greater than the first thermal conductivity of the first substrate core layer 203 and/or the second thermal conductivity of the second substrate core layer 204.

FIG. 3 illustrates a cross-sectional view of an embodiment of a substrate core structure having a semiconductor die layer and a substrate core layer in accordance with example embodiments of the disclosure. The core structure 302 illustrated in FIG. 3 may include a layer of one or more semiconductor dies 303 having a first thermal conductivity, a layer of substrate core material 304 having a second thermal conductivity, and a thermally conductive layer 307 having a third thermal conductivity. Thermally conductive layer 307 may have a first side 308 attached to semiconductor die layer 303 and a second side 309 attached to substrate core layer 304. The third thermal conductivity of thermally conductive layer 307 may be greater than the first thermal conductivity of semiconductor die layer 303 and/or the second thermal conductivity of substrate core layer 304.

Semiconductor die layer 303 may be implemented with any type of semiconductor device such as an electronic integrated circuit (EIC), a photonic integrated circuit (PIC), and/or the like, fabricated from any type of semiconducting material or materials including silicon, GaAs, SiC, SiN, and/or the like, or a combination thereof. Semiconductor die layer 303 may implement any type of functionality including memory, cache, input and/or output (I/O or IO), energy storage (e.g., ISC), and/or any type of logic such as a general and/or specific purpose integrated circuit (e.g., a bridge, a field programmable gate array (FPGA), an application specific integrated circuit (ASIC), a central processing unit (CPU), a graphics processing unit (GPU), a neural processing unit (NPU), tensor processing unit (TPU), data processing unit (DPU), an amplifier, a filter, a modulator and/or demodulator, and/or the like).

In some embodiments, semiconductor die layer 303 may be implemented with multiple semiconductor dies such as a high bandwidth memory (HBM) stack. In some embodiments, semiconductor die layer 303 may include one or more layers forming a power delivery network such as a BSPDN. In some embodiments, semiconductor die layer 303 may have a first side attached to thermally conductive layer 307 and one or more layers forming a power delivery network such as a BSPDN adjacent to a second side of the semiconductor die layer 303.

FIG. 4 illustrates a cross-sectional view of an embodiment of a substrate core structure having an energy storage layer and a substrate core layer in accordance with example embodiments of the disclosure. The core structure 402 illustrated in FIG. 4 may include a layer 403 of one or more energy storage devices (e.g., an ISC) having a first thermal conductivity, a layer of substrate core material 404 having a second thermal conductivity, and a thermally conductive layer 407 having a third thermal conductivity. Thermally conductive layer 407 may have a first side 408 attached to energy storage layer 403 and a second side 409 attached to substrate core layer 404. The third thermal conductivity of thermally conductive layer 407 may be greater than the first thermal conductivity of energy storage layer 403 and/or the second thermal conductivity of substrate core layer 404.

In the embodiments illustrated in FIG. 1 through FIG. 4, as well as any other embodiments disclosed herein, any layer may be attached to any other layer using any suitable technique including one or more bonding techniques such as hybrid bonding, fusion bonding (with or without applied mechanical stress), surface activated bonding, atomic diffusion bonding, plasma activated bonding, adhesive bonding, compression bonding (e.g., thermo-compression bonding (TCB)), hydrophilic direct bonding, and/or the like.

In some embodiments, fusion bonding may include any number of the following processes: flattening and/or cleaning one or both surfaces (e.g., chemically, by polishing, and/or the like), performing surface activation (e.g., using plasma activation, wet chemical solutions, and/or the like), bringing clean and/or activated surfaces into contact (with or without heat, pressure, and/or the like), annealing, and/or the like.

In some embodiments, hybrid bonding techniques may be used to form bonds between metal portions of dies in a stack (e.g., metal-metal bonds) and/or between dielectric portions of dies in a stack (e.g., oxide-oxide bonds). Depending on the implementation details, hybrid bonding may improve thermal performance (e.g., reduce thermal dissipation), reduce the pitch of electrical connections between dies, increase bandwidth between dies, increase device density, and/or the like.

Additionally, or alternatively, any layer may be attached to any other layer using one or more attachment techniques that may be less direct than bonding, for example, using die attach film, micro bumps, and/or the like.

In some embodiments, and depending on the implementation details, attaching (e.g., bonding) layers to two sides of a thermally conductive layer in accordance with example embodiments of the disclosure (a process and/or apparatus that may be referred to as double-sided bonding) may enable the use of the same or similar attachment (e.g., bonding) processes for bonding on both sides of the thermally conductive layer. For example, an existing or newly developed process for bonding a semiconductor or substrate core material to one side of a diamond (e.g., SCD) layer may be exploited to bond another semiconductor or substrate core material to another side of the diamond layer.

In some embodiments, and depending on the implementation details, attaching (e.g., bonding) semiconductor or substrate core materials to two sides of a thermally conductive layer in accordance with example embodiments of the disclosure may exploit existing die stacking, embedding, and/or other assembly processes.

Although the embodiments described herein are not limited to any specific implementation details, diamond (e.g., SCD) may be especially beneficial when used in a thermally conductive layer in some applications. For example, the thermal conductivity of some forms of diamond (e.g., SCD) may be about 1500-2200 times greater than the thermal conductivity of glass, about 10-20 times greater than the thermal conductivity of silicon, and/or about 5-7 times greater than the thermal conductivity of copper. Thus, depending on the implementation details, diamond may improve thermal management in 2.5D and/or 3D semiconductor packages by efficiently spreading hot spots generated by active dies. Depending on the implementation details, the thickness of diamond (e.g., SCD) may be selected to achieve relatively high thermal performance and/or die and/or package size requirements. Moreover, depending on the implementation details, the thickness of diamond (e.g., SCD) may be reduced to reduce costs, possibly with little or no sacrifice in performance.

In some example embodiments, a diamond material such as SCD may have a thermal conductivity within a range of about 1,000 to 2,400 W/mK which may depend on operating temperature, isotopic purity, crystal quality, doping, and/or the like.

In some example embodiments a diamond material such as SCD may have a thermal conductivity within a range that may have a low end of about 500 W/mK, about 600 W/mK, about 700 W/mK, about 800 W/mK, about 900 W/mK, about 1,000 W/mK, about 1,100 W/mK, about 1,200 W/mK, about 1,300 W/mK, about 1,400 W/mK, about 1,500 W/mK, about 1,600 W/mK, about 1,700 W/mK, about 1,800 W/mK, about 1,900 W/mK, about 2,000 W/mK, about 2,100 W/mK, about 2,200 W/mK, about 2,300 W/mK, or about 2,400 W/mK, depending on operating temperature, isotopic purity, crystal quality, doping, and/or the like. In some example embodiments a diamond material such as SCD may have a thermal conductivity within a range that may have a high end of about 1,000 W/mK, about 1,100 W/mK, about 1,200 W/mK, about 1,300 W/mK, about 1,400 W/mK, about 1,500 W/mK, about 1,600 W/mK, about 1,700 W/mK, about 1,800 W/mK, about 1,900 W/mK, about 2,000 W/mK, about 2,100 W/mK, about 2,200 W/mK, about 2,300 W/mK, about 2,400 W/mK, about 2,500 W/mK, about 2,600 W/mK, about 2,700 W/mK, about 2,800 W/mK, about 2,900 W/mK, about 3,000 W/mK, about 3,100 W/mK, about 3,200 W/mK, about 3,300 W/mK, or about 3,400 W/mK, depending on operating temperature, isotopic purity, crystal quality, doping, and/or the like.

In some example embodiments, a semiconductor material such as silicon may have a thermal conductivity within a range of about 130 to 150 W/mK which may depend on operating temperature, isotopic purity, crystal quality, doping, and/or the like. For example, some semiconductor materials such as silicon may have a thermal conductivity of about 150 W/mK at a room temperature of about 23 degrees C.

In some example embodiments a semiconductor material such as silicon may have a thermal conductivity within a range that may have a low end of about 50 W/mK, about 60 W/mK, about 70 W/mK, about 80 W/mK, about 90 W/mK, about 100 W/mK, about 110 W/mK, about 120 W/mK, about 130 W/mK, about 140 W/mK, about 150 W/mK, about 160 W/mK, about 170 W/mK, about 180 W/mK, about 190 W/mK, or about 200 W/mK, depending on operating temperature, isotopic purity, crystal quality, doping, and/or the like. In some example embodiments a semiconductor material such as silicon may have a thermal conductivity within a range that may have a high end of about 100 W/mK, about 110 W/mK, about 120 W/mK, about 130 W/mK, about 140 W/mK, about 150 W/mK, about 160 W/mK, about 170 W/mK, about 180 W/mK, about 190 W/mK, about 200 W/mK, about 210 W/mK, about 220 W/mK, about 230 W/mK, about 240 W/mK, about 250 W/mK, about 260 W/mK, or about 270 W/mK depending on operating temperature, isotopic purity, crystal quality, doping, and/or the like.

In some example embodiments, a glass material such as fused silica, boron-doped aluminosilicate, aluminum borosilicate, and/or the like, may have a thermal conductivity within a range of about 1.1 to 1.7 W/mK which may depend on operating temperature, isotopic purity, crystal quality, doping, and/or the like.

In some example embodiments, a glass material such as fused silica, boron-doped aluminosilicate, aluminum borosilicate, and/or the like, may have a thermal conductivity within a range that may have a low end of about 0.5 W/mK, about 0.6 W/mK, about 0.7 W/mK, about 0.8 W/mK, about 0.9 W/mK, about 1.0 W/mK, about 1.1 W/mK, about 1.2 W/mK, about 1.3 W/mK, about 1.4 W/mK, about 1.5 W/mK, about 1.6 W/mK, about 1.7 W/mK, about 1.8 W/mK, about 1.9 W/mK, or about 2.0 W/mK, depending on operating temperature, isotopic purity, crystal quality, doping, and/or the like. In some example embodiments, a glass material such as fused silica, boron-doped aluminosilicate, aluminum borosilicate, and/or the like, may have a thermal conductivity within a range that may have a high end of about 1.0 W/mK, about 1.1 W/mK, about 1.2 W/mK, about 1.3 W/mK, about 1.4 W/mK, about 1.5 W/mK, about 1.6 W/mK, about 1.7 W/mK, about 1.8 W/mK, about 1.9 W/mK, about 2.0 W/mK, about 2.1 W/mK, about 2.2 W/mK, about 2.3 W/mK, about 2.4 W/mK, about 2.5 W/mK, about 2.6 W/mK, or about 2.7 W/mK, depending on operating temperature, isotopic purity, crystal quality, doping, and/or the like.

In some embodiments, a diamond material such as SCD may be bonded (e.g., fusion bonded) to a semiconductor (e.g., silicon) substrate (e.g., a silicon wafer, panel, and/or the like). Depending on the implementation details, bonding a diamond material such as SCD to a semiconductor (e.g., silicon) substrate may provide a thermal interface that my have a relatively low thermal resistance and/or a relatively high shear strength. For example, in some embodiments, a silicon layer bonded (e.g., bonded directly) to an SCD layer may produce a thermal interface having a thickness of about 3.0 to 3.3 nm, a thermal resistance of about 0.0001 cm2-K/W, and/or a shear strength greater than about 5kgf which may enable heat to pass through the thermal interface relatively easily. Moreover, the coefficient of thermal expansion (CTE) of SCD (e.g., 1.0 ppm/C) may be relatively close to the CTE of silicon (e.g., 2.5 ppm/C for silicon compared to about 18 ppm/C for copper) which may reduce thermal stress and/or improve reliability of a thermal interface.

Although the embodiments described herein are not limited to any specific applications, depending on the implementation details, semiconductor packages in accordance with example embodiments of the disclosure may be especially beneficial for applications such as artificial intelligence (AI), machine learning (ML), CPUs, GPUs, NPUs, TPUs, and/or other applications that may benefit from high performance and/or high power, automotive and/or radio frequency (RF) applications which may involve higher reliability, possibly under hash use conditions, datacenter applications which may involve relatively large packages, and/or the like.

FIGS. 5A through 5C illustrate an embodiment of a method for fabricating a substrate core structure having a thermally conductive layer and a semiconductor layer using a thinning technique in accordance with example embodiments of the disclosure. The substrate core structure 502 illustrated in FIG. 5 may include one or more elements that may be similar to those illustrated in other figures in which similar elements may be indicated by reference numbers ending in, and/or containing, the same digits, letters, and/or the like. The method illustrated with respect to FIGS. 5A through 5C may be used, for example, to fabricate any of the substrate core structures having a semiconductor layer disclosed herein.

FIG. 5A illustrates a cross-sectional view of an embodiment of a semiconductor die having an active layer in accordance with example embodiments of the disclosure. The semiconductor die 510 may have a thickness T1 and an active layer 511 that may include one or more electronic components such as transistors, diodes, and/or the like, one or more photonic components such as lasers, modulators, detectors, amplifiers, quantum wells, and/or the like, and/or any other type of active components. Semiconductor die 510 may be fabricated from any type of semiconducting material or materials and/or may implement any type of functionality for an EIC, a PIC, and/or the like, including any of those described herein.

FIG. 5B illustrates a cross-sectional view of an embodiment of a semiconductor die with semiconductor material removed in accordance with example embodiments of the disclosure. The semiconductor die 510’ may be formed by performing a thinning operation on semiconductor die 510 illustrated in FIG. 5A to remove a portion of semiconductor material shown with dashed lines and having a thickness T3 such that thinned semiconductor die 510’ may have a resulting thickness T2 and a remaining layer of semiconductor material having a surface 512 and a thickness T4 adjacent to the active layer 511. The thickness T4 of the remaining layer of semiconductor material may be any value including zero (e.g., all semiconductor material removed from the bottom of the active layer 511) or a minimum value (e.g., just thick enough) to form a bond (e.g., a fusion bond) between the remaining layer of semiconductor material and a thermally conductive layer. In an embodiment in which all or nearly all semiconductor material may be removed from active layer 511, thinned semiconductor die 510’ may be attached to a thermally conductive layer using an attachment technique such as adhesive bonding.

A thinning operation may be performed, for example, using a wafer or panel thinning operation on a wafer or panel in which die 510 may be fabricated. Examples of thinning operations may include any type of material removal process such as polishing (e.g., chemical mechanical polishing (CMP)), etching, and/or the like.

FIG. 5C illustrates a cross-sectional view of an embodiment of a structure having a thinned semiconductor die attached to a thermally conductive layer in accordance with example embodiments of the disclosure. Surface 512 (illustrated in FIG. 5B) of thinned semiconductor die 510’ may be connected to a thermally conductive layer 507 using any suitable technique such as

fusion bonding and/or any of the techniques described herein. In some embodiments, thinning semiconductor die 510’ may enable thermally conductive layer 507 to be located a distance T4 from active layer 511 which may be relatively close to (or possibly touching) active layer 511. Depending on the implementation details, this may enable the thermally conductive layer 507 to spread heat from one or more hot spots within thinned semiconductor die 510’ and/or active layer 511, thereby reducing the temperature of one or more hot spots and/or die 510’.

In some embodiments, a substrate core layer may be connected to a second side of thermally conductive layer 507. Depending on the implementation details, this may create a stacked structure that may improve heat flow within, into, out of, and/or between semiconductor die 510’, thermally conductive layer 507, and/or the substrate core layer.

FIGS. 6A through 6C illustrate an embodiment of a method for fabricating a substrate core structure having a thermally conductive layer and a substrate core layer using a thinning technique in accordance with example embodiments of the disclosure. The substrate core structure 602 illustrated in FIG. 6 may include one or more elements that may be similar to those illustrated in other figures in which similar elements may be indicated by reference numbers ending in, and/or containing, the same digits, letters, and/or the like. The method illustrated with respect to FIGS. 6A through 6C may be used, for example, to fabricate any of the substrate core structures having one or more substrate core layers disclosed herein.

FIG. 6A illustrates a cross-sectional view of an embodiment of a substrate core layer in accordance with example embodiments of the disclosure. The substrate core layer 610 may have an initial thickness T8 and may be fabricated from any type of type of substrate core material including any of those described herein such as semiconductor, glass, organic, and/or the like.

FIG. 6B illustrates a cross-sectional view of an embodiment of a substrate core layer with core material removed in accordance with example embodiments of the disclosure. Substrate core layer 610’ may be formed by performing a thinning operation on substrate core layer 610 illustrated in FIG. 6A to remove a portion of core material shown with dashed lines and having a thickness T9 such that thinned substrate core layer 610’ may have a resulting thickness T10. A thinning operation may be performed, for example, using a wafer or panel thinning operation on a wafer or panel from which substrate core layer 610 may be fabricated. Examples of thinning operations may include any type of material removal process such as polishing (e.g., chemical mechanical polishing (CMP)), etching, and/or the like.

FIG. 6C illustrates a cross-sectional view of an embodiment of a substrate core structure having a thinned substrate core layer attached to a thermally conductive layer in accordance with example embodiments of the disclosure. Surface 612 (illustrated in FIG. 6B) of thinned substrate core layer 610’ may be connected to a thermally conductive layer 607 using any suitable technique such as fusion bonding and/or any of the techniques described herein. In some embodiments, thinning substrate core layer 610’ may enable thermally conductive layer 607 to be located a relatively short distance T10 from a lamination layer and/or any device attached to the substrate core structure. Depending on the implementation details, this may enable thermally conductive layer 607 to spread and/or remove heat within the substrate core structure and/or one or more devices attached to the substrate core structure.

In some embodiments, an additional layer including a second substrate core layer, a semiconductor die, an energy storage device, and/or the like, may be attached to a second side of thermally conductive layer 607. Depending on the implementation details, this may create a stacked structure that may improve heat flow within, into, out of, and/or between, thinned substrate core layer 610’, thermally conductive layer 607, and/or the additional layer.

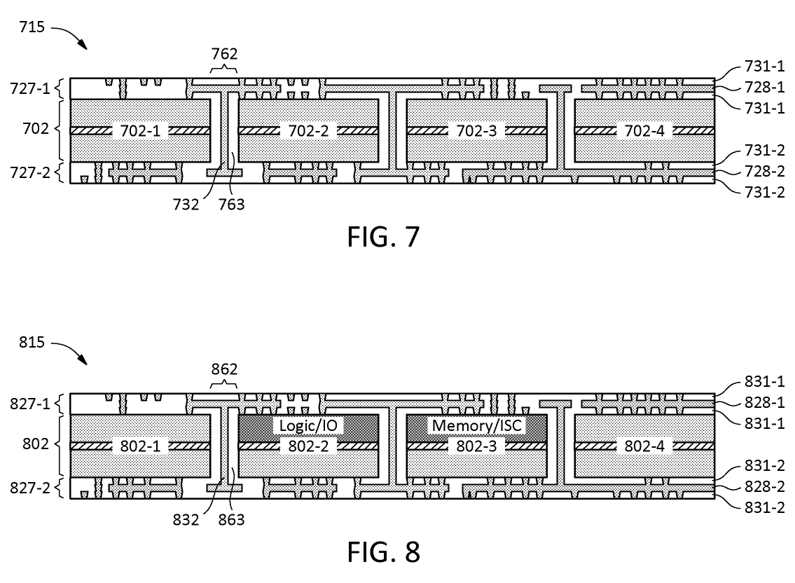

FIG. 7 illustrates a cross-sectional view of the embodiment of a substrate structure having substrate core portions including substrate core layers in accordance with example embodiments of the disclosure. Substrate structure 715 may include one or more elements that may be similar to those illustrated in other figures in which similar elements may be indicated by reference numbers ending in, and/or containing, the same digits, letters, and/or the like.

Substrate structure 715 may include a substrate core structure 702 having one or more substrate core portions 702-1, 702-2, … that may be implemented, for example, using substrate core portions 102 illustrated in FIG. 1 and/or the substrate core structures 202, 302, and/or 402 illustrated in FIG. 2, FIG. 3, and/or FIG. 4, respectively. In this example, one or more substrate core portions 702-1, 702-2, … may be implemented with substrate core structures having a thermally conductive layer stacked between two substrate core layers, but in other embodiments, substrate core portions 702-1, 702-2, … may be implemented with other numbers and/or combinations of layers. Substrate core structure 702 may include one or more gaps 762 between one or more core portions 702 that may be filled with gap filling material 763.

Substrate structure 715 may also include one or more lamination layers 727-1 and/or 727-2 that may provide one or more mechanical, thermal, and/or electrical properties to substrate structure 715. For example, one or more lamination layers 727-1 and/or 727-2 may provide mechanical support to substrate core portions 702-1, 702-2, … which, depending on the implementation details, may result in a relatively rigid substrate structure 715.

In some embodiments, one or more lamination layers 727-1 and/or 727-2 may be implemented with first redistribution layer (RDL) and/or build up layer formed on a first side (e.g., top or front side) and a second RDL and/or build up layer formed on a second side (e.g., bottom or back side) of substrate structure core 702. In some embodiments, and depending on context, one or more of lamination layers 727-1 and/or 727-2 may be referred to and/or characterized as being part of the substrate 715.

Gap filling material 763 may be formed, for example, as part or one or more of lamination layers 727-1 and/or 727-2. One or more vias 763 may be formed in gap filling material 763 to provide one or more electrical connections between one or more RDLs formed with one or more of lamination layers 727-1 and/or 727-2, one or more substrate core portions 702-1, 702-2, … , one or more semiconductor dies and/or other devices attached to one or more sides of substrate structure 715, and/or the like. One or more vias 732 may be implemented, for example, with through organic vias (TOVs).

For purposes of illustration, lamination layers 727-1 and/or 727-2 may be shown as one or more RDLs which may be implemented with one or more layers of dielectric and one or more layers of conductors. For example, an RDL may include a first layer of dielectric material 731 that may function as a substrate or base for the RDL structure. A layer 728 of conductive traces (e.g., using metal such as copper, aluminum, and/or the like) may be formed (e.g., using one or more deposition and/or patterning techniques) on dielectric layer 731 to create a network of electrical connections. One or more additional layers of dielectric material 731 and/or conductive material may be formed over the dielectric layer 731 and/or the first conductive layer 728 depending on the number and/or complexity of connections to be used in the RDL. An RDL may further include one or more layers of vias and/or other connecting structures that may connect conductive traces on one layer with conductive traces on another layer and/or with one or more pads or other structures and/or devices such as semiconductor dies, energy storage devices, HBM stacks, modules, and/or the like, connected to an RDL.

Depending on the implementation details, the use of one or more thermally conductive layers (e.g., SCD) in substrate core portions 702-1, 702-2, … may efficiently dissipate hot spots within, and/or transfer heat between, one or more substrate core portions 702-1, 702-2, one or more lamination layers 727-1 and/or 727-2 (e.g., RDLs), one or more semiconductor dies and/or other devices attached to one or more sides of substrate structure 715, and/or the like.

FIG. 8 illustrates a cross-sectional view of the embodiment of a substrate structure having substrate core portions including at least one substrate core layer and one or more semiconductor die layers in accordance with example embodiments of the disclosure. Substrate structure 815 may include one or more elements that may be similar to those illustrated in other figures in which similar elements may be indicated by reference numbers ending in, and/or containing, the same digits, letters, and/or the like.

Substrate structure 815 may include a substrate core structure 802 having one or more substrate core portions 802-1, 802-2, … that may be implemented, for example, using substrate core portions 102 illustrated in FIG. 1 and/or substrate core structures 202, 302, and/or 402 illustrated in FIG. 2, FIG. 3, and/or FIG. 4, respectively. In this example, one or more substrate core portions 802-1 and/or 802-4 may be implemented with substrate core structures having a thermally conductive layer stacked between two substrate core layers similar to substrate core portions 702-1 and/or 702-4 illustrated in FIG. 7. Additionally, or alternatively, substrate core portion 802-2 may be implemented with a substrate core structure having a thermally conductive layer stacked between a substrate core layer and a semiconductor die that may implement one or more logic and/or IO functions. Additionally, or alternatively, substrate core portion 802-3 may be implemented with a substrate core structure having a thermally conductive layer stacked between a substrate core layer and a third layer that may include a semiconductor die layer that may implement one or more memory functions and/or an energy storage layer that may implement an ISC. In other embodiments, however, substrate core portions 802-1, 802-2, 802-3, 802-4, … may be implemented with other numbers and/or combinations of layers.

Substrate core structure 802 may include one or more gaps 862 between one or more substrate core portions 802 that may be filled with gap filling material 863. Gap filling material 863 may be formed, for example, as part or one or more of lamination layers 827-1 and/or 827-2. One or more vias 832 may be formed in gap filling material 863 to provide one or more electrical connections between one or more RDLs formed with one or more of lamination layers 827-1 and/or 827-2.

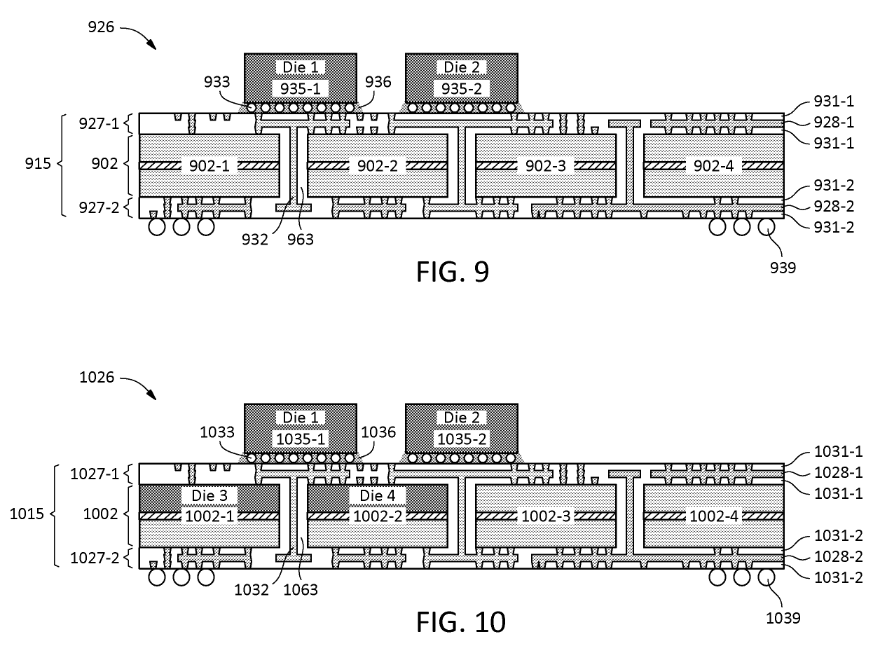

FIG. 9 illustrates a cross-sectional view of an embodiment of a package architecture having a substrate structure with stacked core layers and one or more dies attached to the substrate structure in accordance with example embodiments of the disclosure. Package architecture 926 may include one or more elements that may be similar to those illustrated in FIG. 7 and/or other figures in which similar elements may be indicated by reference numbers ending in, and/or containing, the same digits, letters, and/or the like. For example, package architecture 926 may include a substrate structure 915 having one or more core portions 902, one or more RDL and/or build up layers 927-1 and/or 927-2, and/or one or more vias 932.

However, package architecture 926 may include one or more semiconductor die structures 935-1, 935-2, … attached to one or more sides of substrate structure 915 and electrically connected to one or more RDL and/or build up layers 927-1 and/or 927-2. One or more of semiconductor die structures 935-1 (Die 1), 935-2 (Die 2), … may be implemented with one or more dies that may implement HBM, memory, cache, IO, energy storage (e.g., ISC), FPGA, ASIC, CPU, GPU, NPU, TPU, DPU, and/or the like.

One or more of die structures 935 may be attached to one or more RDL and/or build up layers 927 using any suitable technique such as one or more solder connections (e.g., solder balls) 933. In some embodiments, one or more materials such as molded underfill (MUF), epoxy molding compound (EMC), and/or the like, may be used for underfill 936 between solder connections.

Depending on the implementation details, implementing package architecture 926 with one or more core portions 902 having a thermally conductive layer may improve the thermal conductivity of substrate structure 915 which may enable wider bandwidth, faster speed, and/or higher memory and/or compute and/or logic capacity, while possibly improving thermal performance (e.g., reducing or eliminating hot spots).

In some embodiments, package architecture 926 may include one or more connections (e.g., solder connections such as solder balls) 939 to connect package architecture 926 to one or more interposers, circuit boards, and/or the like.

In other embodiments, other numbers and/or combinations of substrate core portions 902, semiconductor die structures 935, and/or layers implemented therein, may be used.

FIG. 10 illustrates a cross-sectional view of an embodiment of a package architecture having a substrate with stacked core layers with one or more semiconductor die layers and one or more dies attached to the substrate in accordance with example embodiments of the disclosure. Package architecture 1026 may include one or more elements that may be similar to those illustrated in FIG. 9 and/or other figures in which similar elements may be indicated by reference numbers ending in, and/or containing, the same digits, letters, and/or the like. For example, package architecture 1026 may include a substrate 1015 having one or more core portions 1002, one or more RDL and/or build up layers 1027-1 and/or 1027-2, one or more vias 1032, one or more semiconductor die structures 1035 attached to one or more RDL and/or build up layers 1027 using any suitable technique such as one or more solder connections (e.g., solder balls) 1033 and/or underfill compound (e.g., MUF, EMC, and/or the like) 1036 between solder connections, and/or one or more connections (e.g., solder connections such as solder balls) 1039 to connect package architecture 1026 to one or more interposers, circuit boards, and/or the like.

However, package architecture 1026 may include one or more core portions 1002 having at least one semiconductor die layer. For example, core portion 1002-1 may include a semiconductor die (Die 3), and/or core portion 1002-2 may include a semiconductor die (Die 4), either of which may implement any type of functionality including memory (e.g., HBM), cache, input and/or output (I/O or IO), energy storage (e.g., ISC), and/or any type of logic such as a general and/or specific purpose integrated circuit (e.g., bridge, FPGA, ASIC, CPU, GPU, NPU, TPU, DPU, and/or the like).

In one example embodiment, Die 3 in core portion 1002-1 may be implemented with an ISC, and Die 4 in core portion 1002-2 may be implemented with a semiconductor bridge. In such an embodiment, bridge Die 4 in core portion 1002-2 may function as an active bridge to connect Die 1 and Die 2 in semiconductor die structures 935-1 and 935-2, respectively, while the ISC in core portion 1002-1 may improve power delivery performance (e.g., power delivery through substrate 1015 and/or one or more power delivery networks (PDNs) in one or more dies) by locating one or more capacitors relatively close to one or more semiconductor dies.

Depending on the implementation details, the use of one or more thermally conductive layers in one or more of core portions 1002 may help dissipate hot spots, and/or remove heat from Die 3 and/or Die 4, as well as any other sources of heat related to package architecture 1026.

In other embodiments, other numbers and/or combinations of substrate core portions 1002, semiconductor die structures 1035, and/or layers implemented therein, may be used.

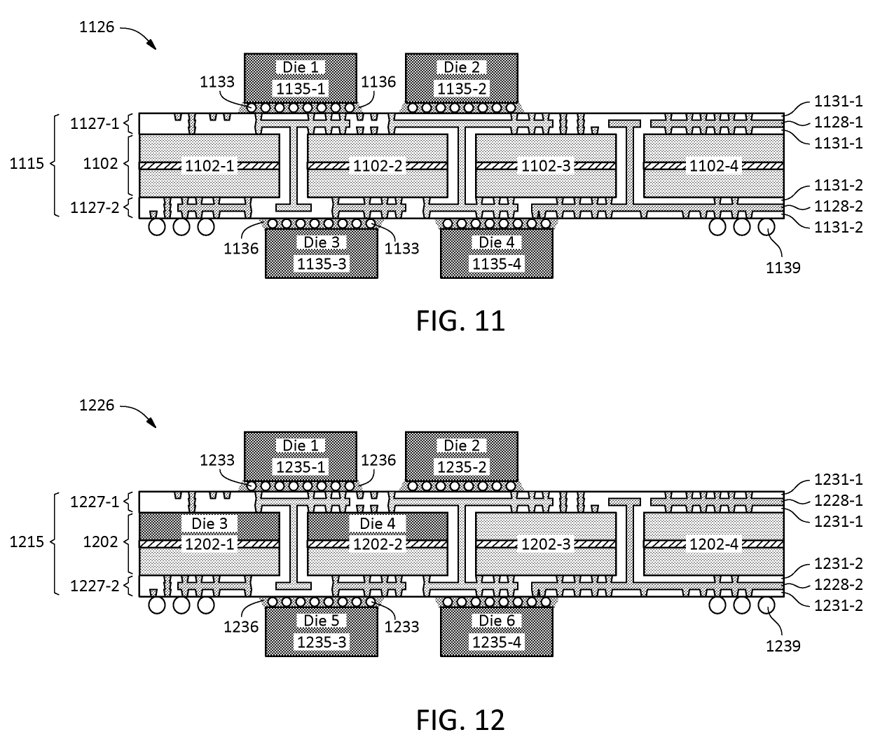

FIG. 11 illustrates a cross-sectional view of an embodiment of a package architecture having a substrate with stacked core layers with substrate core layers and one or more dies attached to the substrate in accordance with example embodiments of the disclosure. Package architecture 1126 may include one or more elements that may be similar to those illustrated in FIG. 9 and/or other figures in which similar elements may be indicated by reference numbers ending in, and/or containing, the same digits, letters, and/or the like. For example, package architecture 1126 may include a substrate 1115 having one or more core portions 1102, one or more RDL and/or build up layers 1127-1 and/or 1127-2, one or more semiconductor die structures 1135-1 (Die 1) and/or 1135-2 (Die 2) attached to RDL and/or build up layer 1127-1, and/or one or more connections (e.g., solder connections such as solder balls) 1139 to connect package architecture 1126 to one or more interposers, circuit boards, and/or the like.

However, package architecture 1126 may include one or more additional semiconductor die structures 1135-3 (Die 3) and/or 1135-4 (Die 4) attached to RDL and/or build up layer 1127-2. In some embodiments, semiconductor die structures 1135-3 (Die 3) and/or 1135-4 (Die 4) may implement any type of functionality including memory (e.g., HBM), cache, input and/or output (I/O or IO), energy storage (e.g., ISC), and/or any type of logic such as a general and/or specific purpose integrated circuit (e.g., bridge, FPGA, ASIC, CPU, GPU, NPU, TPU, DPU, and/or the like).

Semiconductor die structures 1135-3 (Die 3) and/or 1135-4 (Die 4), as well as semiconductor die structures 1135-1 (Die 1) and/or 1135-2 (Die 2), may be attached to one or more of RDL and/or build up layers 1127-1 and/or 1127-2 using any suitable technique such as one or more solder connections (e.g., solder balls) 1133 and/or underfill compound (e.g., MUF, EMC, and/or the like) 1136 between solder connections.

In other embodiments, other numbers and/or combinations of substrate core portions 1102, semiconductor die structures 1135, and/or layers implemented therein, may be used.

FIG. 12 illustrates a cross-sectional view of an embodiment of a package architecture having a substrate with stacked core layers with one or more semiconductor die layers and one or more dies attached to two sides of the substrate in accordance with example embodiments of the disclosure. Package architecture 1226 may include one or more elements that may be similar to those illustrated in FIG. 10 and/or other figures in which similar elements may be indicated by reference numbers ending in, and/or containing, the same digits, letters, and/or the like. For example, package architecture 1226 may include a substrate 1215 having one or more core portions 1202-1 and/or 1202-2 having one or more semiconductor die layers (Die 3 and/or Die 4, respectively), one or more RDL and/or build up layers 1227-1 and/or 1227-2, one or more semiconductor die structures 1235-1 (Die 1) and/or 1235-2 (Die 2) attached to RDL and/or build up layer 1227-1, and/or one or more connections (e.g., solder connections such as solder balls) 1239 to connect package architecture 1226 to one or more interposers, circuit boards, and/or the like.

However, package architecture 1226 may include one or more additional semiconductor die structures 1235-3 (Die 5) and/or 1235-4 (Die 6) attached to RDL and/or build up layer 1227-2. In some embodiments, semiconductor die structures 1235-3 (Die 5) and/or 1235-4 (Die 6) may implement any type of functionality including memory (e.g., HBM), cache, input and/or output (I/O or IO), energy storage (e.g., ISC), and/or any type of logic such as a general and/or specific purpose integrated circuit (e.g., bridge, FPGA, ASIC, CPU, GPU, NPU, TPU, DPU, and/or the like).

Semiconductor die structures 1235-3 (Die 5) and/or 1235-4 (Die 6), as well as semiconductor die structures 1235-1 (Die 1) and/or 1235-2 (Die 2), may be attached to one or more of RDL and/or build up layers 1227-1 and/or 1227-2 using any suitable technique such as one or more solder connections (e.g., solder balls) 1233 and/or underfill compound (e.g., MUF, EMC, and/or the like) 1236 between solder connections.

In other embodiments, other numbers and/or combinations of substrate core portions 1202, semiconductor die structures 1235, and/or layers implemented therein, may be used.

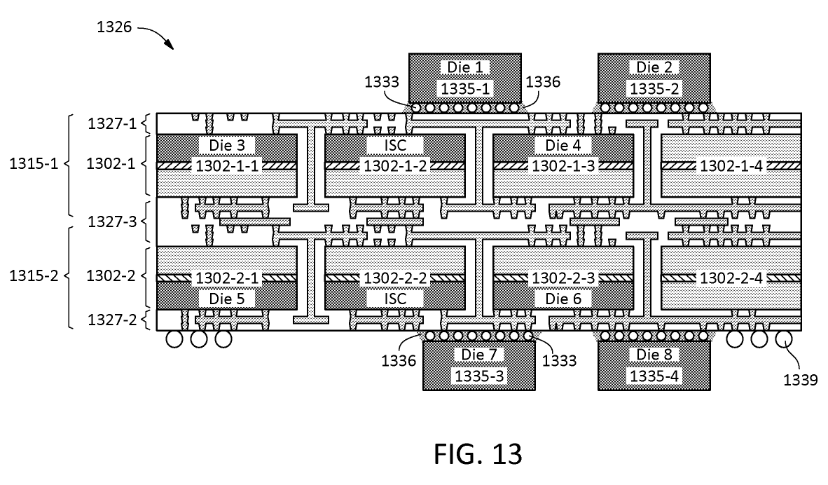

FIG. 13 illustrates a cross-sectional view of an embodiment of a package architecture having two stacked substrates with stacked core layers having one or more semiconductor die layers and one or more dies attached to two sides of the stacked substrates in accordance with example embodiments of the disclosure. Package architecture 1326 may include one or more elements that may be similar to those illustrated in FIG. 12 and/or other figures in which similar elements may be indicated by reference numbers ending in, and/or containing, the same digits, letters, and/or the like. For example, package architecture 1326 may include a first substrate core structure 1302-1 having one or more core portions 1302-1-1 and/or 1302-1-3 having one or more semiconductor die layers (Die 3 and/or Die 4, respectively), one or more RDL and/or build up layers 1327-1 and/or 1327-2, one or more semiconductor die structures 1335-1 (Die 1) and/or 1335-2 (Die 2) attached to RDL and/or build up layer 1327-1, one or more semiconductor die structures 1335-3 (Die 7) and/or 1335-4 (Die 8) attached to RDL and/or build up layer 1327-2, and/or one or more connections (e.g., solder connections such as solder balls) 1339 to connect package architecture 1326 to one or more interposers, circuit boards, and/or the like.

However, package architecture 1326 may include a second substrate core structure 1302-2 having one or more core portions 1302-2-1 and/or 1302-2-3 having one or more semiconductor die layers (Die 5 and/or Die 6, respectively) stacked between first substrate core structure 1302-1 and RDL and/or build up layer 1327-2. Package architecture 1326 may include a third RDL and/or build up layer 1327-3 stacked between first substrate core structure 1302-1 and second substrate core structure 1302-2.

In some embodiments, the semiconductor die layer (Die 4) in core portion 1302-1-3 may operate as an active bridge between semiconductor die structures 1335-1 (Die 1) and 1335-2 (Die 2). Additionally, or alternatively, in some embodiments, the semiconductor die layer (Die 6) in core portion 1302-2-3 may operate as an active bridge between semiconductor die structures 1335-3 (Die 7) and 1335-4 (Die 8).

In some embodiments, one or more of core portion 1302-1-2 in substrate core structure 1302-1 and/or core portion 1302-2-2 in substrate core structure 1302-2 may include an energy storage device (e.g., ISC). Depending on the implementation details, this may improve power delivery performance including, for example, the performance of one or more PDNs (e.g., BSPDNs) in any semiconductor die included in package architecture 1326.

In other embodiments, other numbers and/or combinations of substrate core portions 1302, semiconductor die structures 1335, and/or layers implemented therein, may be used.

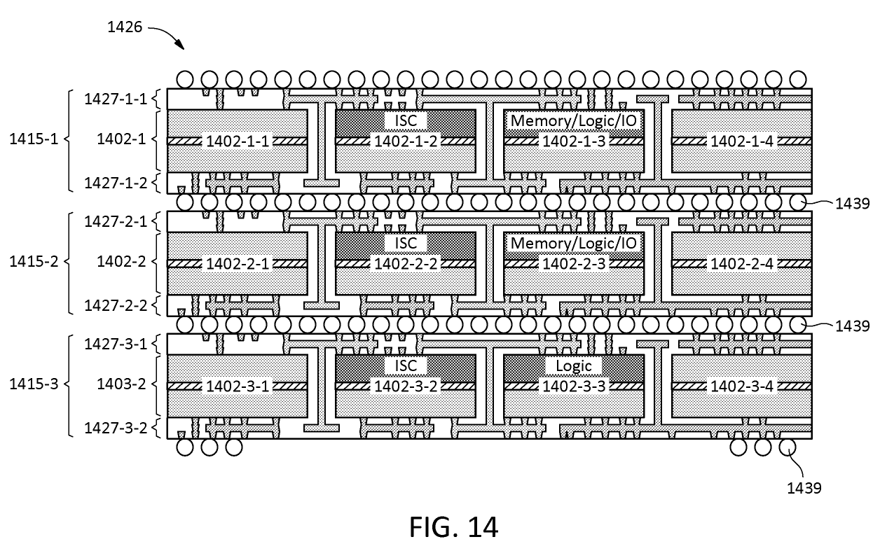

FIG. 14 illustrates a cross-sectional view of an embodiment of a package architecture having two or more stacked substrates with stacked core layers having one or more semiconductor die layers in accordance with example embodiments of the disclosure. Package architecture 1426 may include one or more elements that may be similar to those illustrated in FIG. 8 and/or other figures in which similar elements may be indicated by reference numbers ending in, and/or containing, the same digits, letters, and/or the like. For example, package architecture 1426 may include two or more stacked substrate structures 1415-1, 1415-2, … that may be implemented, for example, with substrate structures similar to those illustrated in FIG. 8. In this example, substrate structures 1415-1, 1415-2, and/or 1415-3 may include core portions 1402-1-1, 1402-1-4, 1402-2-1, 1402-2-4, 1402-3-1, and/or 1402-3-4 that may include thermally conductive layers stacked between substrate core layers. Additionally, or alternatively, substrate structures 1415-1, 1415-2, and/or 1415-3 may include core portions 1402-1-3, 1402-2-3, and/or 1402-3-3 having semiconductor die layers that may implement memory, logic, IO, and/or other functionality. Additionally, or alternatively, substrate structures 1415-1, 1415-2, and/or 1415-3 may include core portions 1402-1-2, 1402-2-2, and/or 1402-3-2 implemented with energy storage devices such as ISCs.

Stacked substrate structures 1415 may be attached, for example, using solder connections 1439 and/or other types of electrical and/or mechanical connections.

In other embodiments, other numbers and/or combinations of substrate structures 1415, substrate core portions 1402, and/or layers implemented therein, may be used.

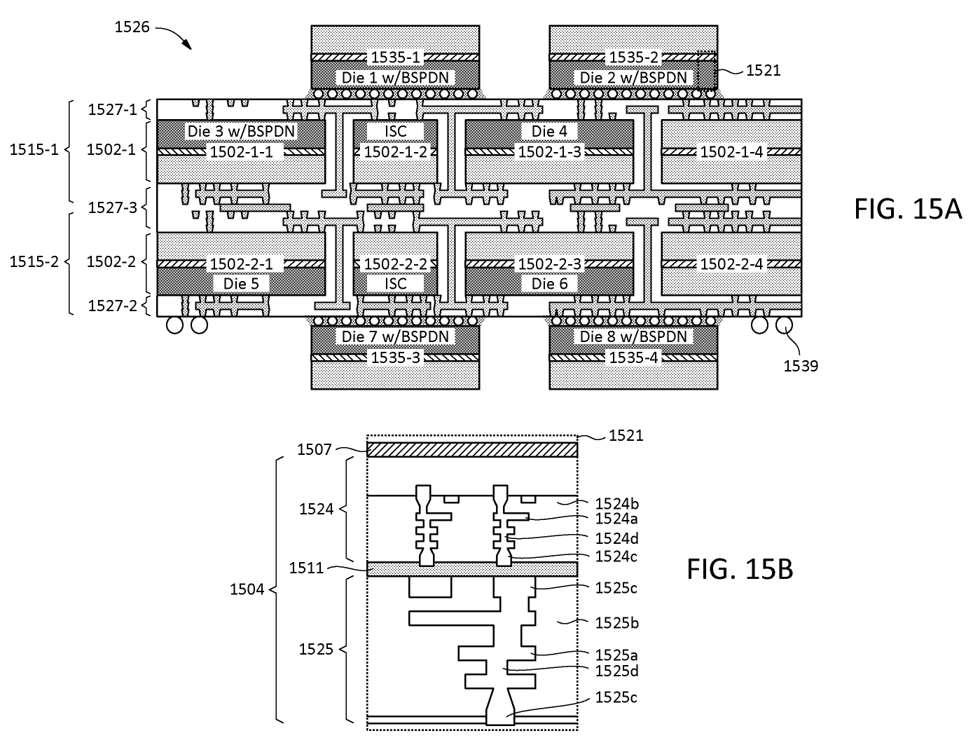

FIG. 15A illustrates a cross-sectional view of an embodiment of a package architecture having at least one substrate with one or more portions having stacked core layers with one or more semiconductor die layers and one or more semiconductor dies attached to the substrate, wherein at least one of the semiconductor die layers and/or semiconductor dies includes a backside power distribution network in accordance with example embodiments of the disclosure.

An enlarged view of an example embodiment of a portion of semiconductor die structure 1535-2 indicated by dotted line box 1521 is illustrated in FIG. 15B.

Referring to FIG. 15A, package architecture 1526 may include one or more elements that may be similar to those illustrated in FIG. 13 and/or other figures in which similar elements may be indicated by reference numbers ending in, and/or containing, the same digits, letters, and/or the like. For example, package architecture 1526 may include a first substrate core structure 1502-1 having one or more core portions 1502-1-1 and/or 1502-1-3 having one or more semiconductor die layers (Die 3 and/or Die 4, respectively) and/or a core portion 1502-1-2 having an ISC, a second substrate core structure 1502-2 having one or more core portions 1502-2-1 and/or 1502-2-3 having one or more semiconductor die layers (Die 5 and/or Die 6, respectively) and/or a core portion 1502-2-2 having an ISC, one or more RDL and/or build up layers 1527-1, 1527-2, and/or 1527-3, one or more semiconductor die structures 1535-1 (including Die 1) and/or 1535-2 (including Die 2) attached to RDL and/or build up layer 1527-1, one or more semiconductor die structures 1535-3 (including Die 7) and/or 1535-4 (including Die 8) attached to RDL and/or build up layer 1527-2, and/or one or more connections (e.g., solder connections such as solder balls) 1539 to connect package architecture 1526 to one or more interposers, circuit boards, and/or the like.

However, in package architecture 1526, one or more semiconductor dies and/or die layers may include a BSPDN. For purposes of illustration, semiconductor die structures 1535-1 (including Die 1), 1535-2 (including Die 2), 1535-3 (including Die 7), 1535-4 (including Die 8), and/or substrate core portion 1502-1-1 (including Die 3) may include BSPDNs. In other embodiments, however, other numbers and/or combinations of substrate structures 1515, substrate cores and/or core portions 1502, layers implemented therein, power distribution networks, and/or the like, may be used.

In some embodiments, the use of a BSPDN may improve power delivery to a semiconductor die (e.g., an ASIC), for example, by reducing routing congestion (e.g., back end of line (BEOL)), by separating the power delivery network from one or more signal layers, and/or the like. Depending on the implementation details, the use of one or more semiconductor die structures 1535 and/or substrate core portions 1502 having semiconductor dies with a BSPDN attached (e.g., bonded) to a thermally conductive layer (e.g., an SCD layer) may further improve power delivery performance, for example, by spreading and/or removing heat from hot spots, thereby improving performance of a semiconductor die.

FIG. 15B illustrates an enlarged cross-sectional view of a portion of the semiconductor die structure indicated by the dotted line box 1521 in FIG. 15A. Referring to FIG. 15B, semiconductor die structure 1535-2 may include a semiconductor die 1504 bonded to a thermally conductive layer 1507. Semiconductor die 1504 may include a signal network 1524, an active layer 1511, and/or a power delivery network 1525. In this example, semiconductor die 1504 may be implemented with an ASIC, but any other type of die may be used.

Signal network 1524 may include one or more layers of conductive traces 1524a formed in a dielectric material 1524b. A signal network 1524 may also include one or more pads 1524c and/or vias 1524d to make connections with, and/or transfer signals using, the one or more layers of conductive traces 1524a.

Power delivery network 1525 may include one or more layers of conductive traces 1525a formed in a dielectric material 1525b that may be formed in one or more layers. A power delivery network 1525 may also include one or more pads 1525c and/or vias 1525d to make connections with, and/or transfer power using, the one or more layers of conductive traces 1525a.

Any or all of traces 1524a and/or 1525a, pads 1524c and/or 1525c, and/or vias 1524d and/or 1525d may be fabricated, for example, with any suitable conductive material(s) including metals such as copper, aluminum, and/or alloys thereof.

In this example, a power delivery network 1525 may implement a BSPDN, but other types of power delivery networks may be used.

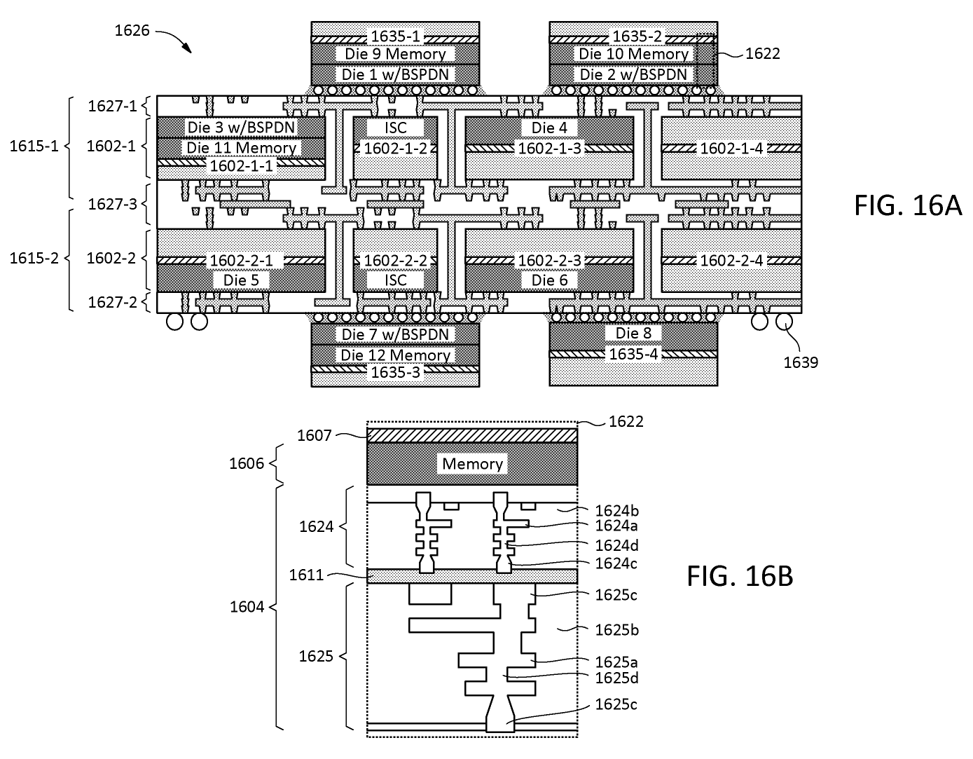

FIG. 16A illustrates a cross-sectional view of an embodiment of a package architecture having at least one substrate with one or more portions having stacked core layers with one or more semiconductor die layers and one or more semiconductor dies attached to the substrate, wherein at least one of the semiconductor die layers and/or semiconductor dies includes a backside power distribution network and/or a second semiconductor die layer in accordance with example embodiments of the disclosure. An enlarged view of an example embodiment of a portion of semiconductor die structure 1635-2 indicated by dotted line box 1622 is illustrated in FIG. 16B.

Referring to FIG. 16A, package architecture 1626 may include one or more elements that may be similar to those illustrated in FIG. 15 and/or other figures in which similar elements may be indicated by reference numbers ending in, and/or containing, the same digits, letters, and/or the like. For example, package architecture 1626 may include a first substrate core structure 1602-1 having one or more core portions 1602-1-1 and/or 1602-1-3 having one or more semiconductor die layers (Die 3 which may have a BSPDN and/or Die 4, respectively). Substrate core structure 1602-1 may further include a core portion 1602-1-2 having an ISC. Package architecture 1626 may include a second substrate core structure 1602-2 having one or more core portions 1602-2-1 and/or 1602-2-3 having one or more semiconductor die layers (Die 5 and/or Die 6, respectively) and/or a BSPDN. Substrate core structure 1602-2 may further include a core portion 1602-2-2 having an ISC. Package architecture 1626 may also include one or more RDL and/or build up layers 1627-1, 1627-2, and/or 1627-3, one or more semiconductor die structures 1635-1 (including Die 1 which may have a BSPDN) and/or 1635-2 (including Die 2 which may have a BSPDN) attached to RDL and/or build up layer 1627-1, one or more semiconductor die structures 1635-3 (including Die 7 which may have a BSPDN) and/or 1635-4 (including Die 8) attached to RDL and/or build up layer 1627-2, and/or one or more connections (e.g., solder connections such as solder balls) 1639 to connect package architecture 1626 to one or more interposers, circuit boards, and/or the like.

However, in package architecture 1626, one or more semiconductor die structures 1635 and/or core portions 1602 may include a second semiconductor die layer that may implement any function including, for example, a support function for the first semiconductor die layer. For purposes of illustration, semiconductor die structures 1635-1 (including Die 1 and Die 9), 1635-2 (including Die 2 and Die 10), and/or 1635-3 (including Die 7 and Die 12), and/or core portion 1602-1-1 (including Die 3 and Die 11) may include a second semiconductor die (e.g., Die 9, Die 10, Die 11, and/or Die 12) that may provide a support function (e.g., memory) for a first semiconductor die (e.g., Die 1, Die 2, Die 3, and/or Die 7, respectively). In other embodiments, however, other numbers and/or combinations of substrate structures 1615, substrate cores and/or core portions 1602, layers implemented therein including one or more semiconductor die layers, power distribution networks, functions, support functions, and/or the like, may be used.

In some embodiments, a second semiconductor die (e.g., Die 9, Die 10, Die 11, and/or Die 12) may have a first side attached (e.g., bonded) to a thermally conductive layer (e.g., SCD), and a second side attached (e.g., bonded, for example, using hybrid bonding) to the corresponding first semiconductor die (e.g., Die 1, Die 2, Die 3, and/or Die 7, respectively). In some embodiments, the first semiconductor die may be implemented with an active die (e.g., an ASIC die) with a BSPDN stacked with the second semiconductor die which may be implemented, for example, with memory (e.g., HBM) and/or IO devices. The second semiconductor die may be attached to a thermally conductive layer such that the resulting structure may provide memory integration solutions to microelectronic devices with relatively wider bandwidth, faster speed, and/or larger capacity, while reducing or eliminating hot spot issues.

FIG. 16B illustrates an enlarged cross-sectional view of a portion of the semiconductor die structure indicated by the dotted line box 1622 in FIG. 16A. The embodiment illustrated in FIG. 16B may include one or more elements that may be similar to those illustrated in FIG. 15B and/or other figures in which similar elements may be indicated by reference numbers ending in, and/or containing, the same digits, letters, and/or the like.

However, the portion of semiconductor die structure 1635-2 illustrated in FIG. 16B may also include a second semiconductor die layer 1606 attached (e.g., bonded) between first semiconductor die layer 1604 and thermally conductive layer 1607. In this example, first semiconductor die layer 1604 may be implemented with an ASIC having a BSPDN 1625, and second semiconductor die layer 1606 may be implemented with one or more memory devices (e.g., for use by first semiconductor die layer 1604), but other types of dies may be used. In this example, a power delivery network 1625 may implement a BSPDN, but other types of power delivery networks may be used.

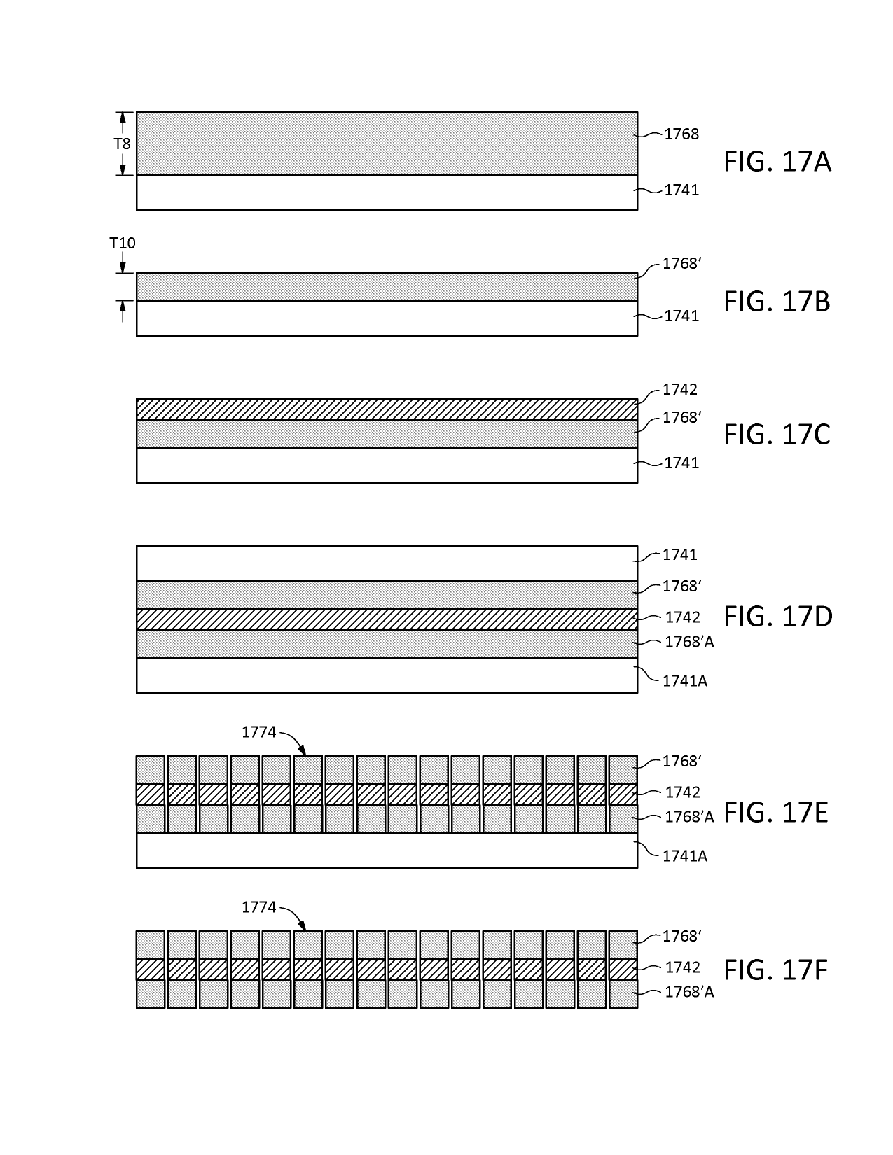

FIGS. 17A through 17F illustrate cross-sectional views of embodiments of operations for a method for fabricating one or more substrate core portions having substrate core layers attached to a thermally conductive layer, and one or more core portions produced thereby, in accordance with example embodiments of the disclosure.

Referring to FIG. 17A, a first substrate core layer 1768 (e.g., a semiconductor material, glass material, organic material, and/or the like) may be attached to a first carrier 1741. First substrate core layer 1768 may have an initial thickness of T8.

Referring to FIG. 17B, first substrate core layer 1768 may be thinned to generate a modified first substrate core layer 1768′ having a thickness of T10 using a thinning operation that may include any type of material removal process such as polishing (e.g., CMP), etching, and/or the like. Although the principles disclosed herein are not limited to any specific implementation details, in some example embodiments, a value of T10 may be 10 μm or less.

Referring to FIG. 17C, a layer of thermally conductive material 1742 (e.g., diamond such as SCD) may be attached (e.g., bonded) to modified first substrate core layer 1768′ using, for example, a wafer-on-wafer (WOW) bonding process.

Although the principles disclosed herein are not limited to any specific implementation details, in some example embodiments, thermally conductive material 1742 may have a thickness between about 2 μm and 400 μm. In an embodiment in which thermally conductive material 1742 may be implemented with diamond (e.g., SCD), a lid may be referred to as a diamond lid.

Referring to FIG. 17D, that assembly of first carrier 1741, modified first substrate core layer 1768′, and/or thermally conductive layer 1742 is flipped upside down, and another assembly including a second carrier 1741A and a modified second layer of substrate core layer 1768′A is attached (e.g., bonded) to thermally conductive layer 1742 using, for example, a WOW bonding process. The second assembly of second carrier 1741A and second layer of substrate core layer 1768′A may be fabricated, the same or similar operations illustrated in FIGS. 17A through 17C.

Referring to FIG. 17E, a singulation process may be performed to singulate one or more substrate core portions 1774 which may be referred to as stacks or core stacks. Singulation may be performed by cutting, dicing, and/or any other suitable process.

Referring to FIG. 17F, singulated substrate core portions 1774 (which may also be referred to as substrate core assemblies) may be removed from second carrier 1741A and used, for example, to fabricate any of the substrate core portions having a thermally conductive layer stacked between two substrate core layers disclosed herein.

FIGS. 18A through 18F illustrate cross-sectional views of embodiments of operations for a method for fabricating one or more substrate core portions having a substrate core layer attached to a first side of a thermally conductive layer and a semiconductor die layer attached to a second side of the thermally conductive layer, and one or more core portions produced thereby, in accordance with example embodiments of the disclosure. The embodiments illustrated in FIGS. 18A through 18F may include one or more elements and/or use one or more operations and/or processes that may be similar to those illustrated in FIGS. 17A through 17F and/or other figures in which similar elements may be indicated by reference numbers ending in, and/or containing, the same digits, letters, and/or the like.

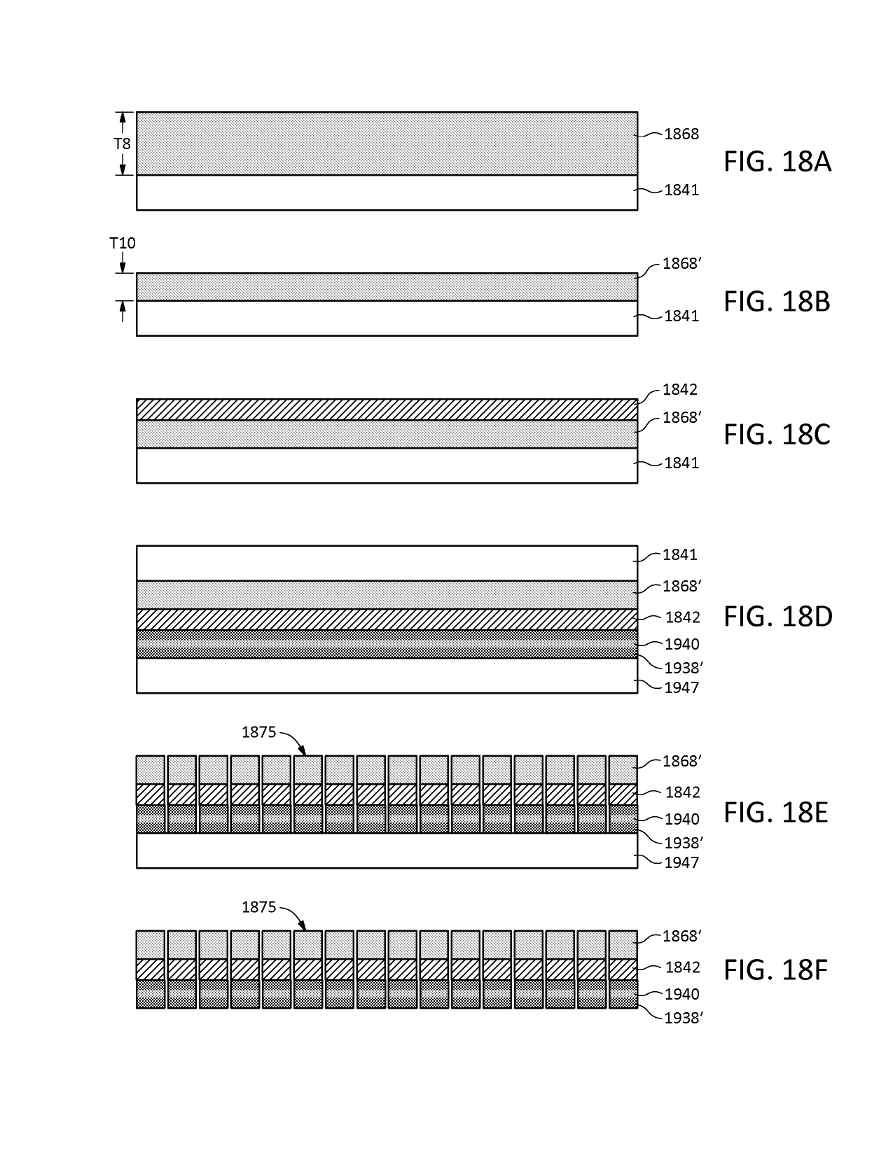

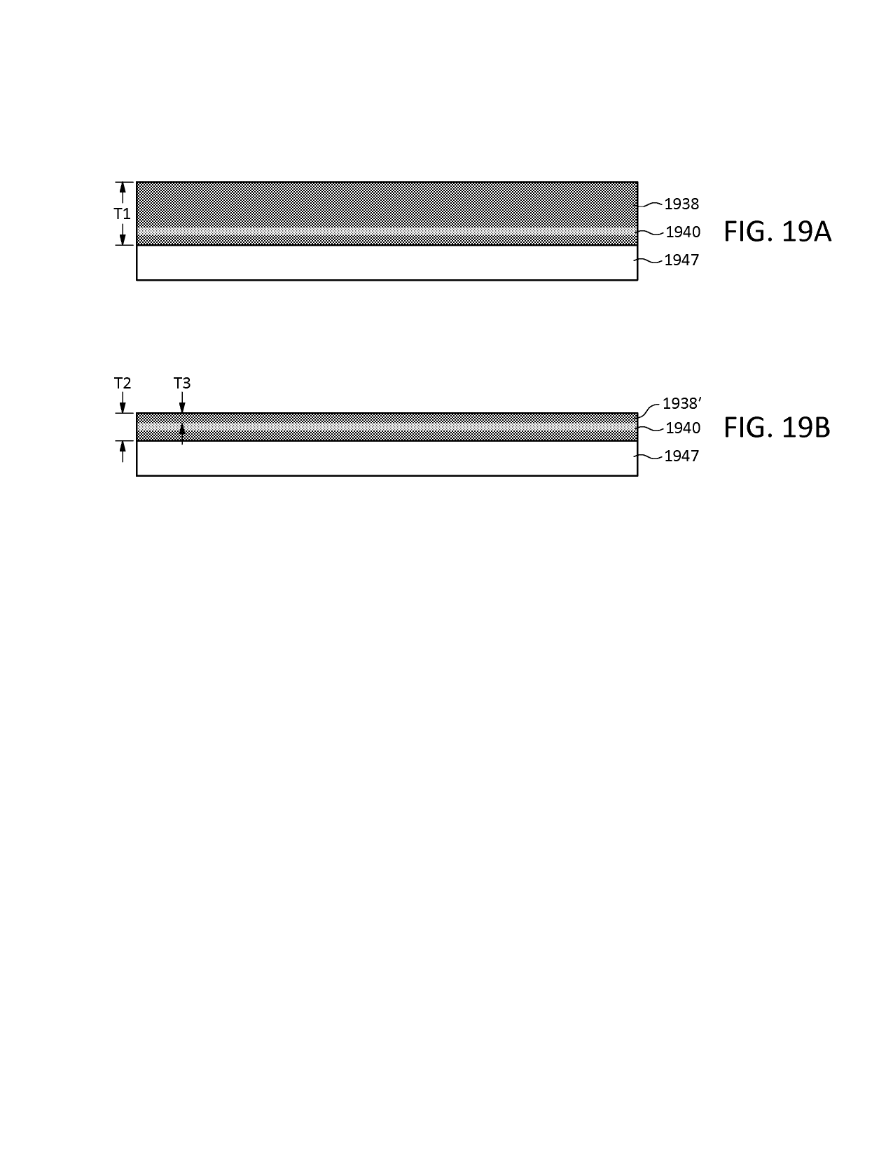

However, in the embodiments illustrated in FIGS. 18D through 18F, an assembly including a modified semiconductor die layer 1938′ (including an active layer 1940) attached to a second carrier 1947 may be substituted for the second carrier and modified second layer of substrate core layer illustrated in FIGS. 17D through 17F. The assembly including modified semiconductor die layer 1938′ attached to second carrier 1947 may be fabricated, for example, using the embodiments illustrated and described with respect to FIGS. 19A through 19B.

Referring to FIG. 18A, a first substrate core layer 1868 (e.g., a semiconductor material, glass material, organic material, and/or the like) may be attached to a first carrier 1841. First substrate core layer 1868 may have an initial thickness of T8.

Referring to FIG. 18B, first substrate core layer 1868 may be thinned to generate a modified first substrate core layer 1868′ having a thickness of T10 using a thinning operation that may include any type of material removal process such as polishing (e.g., CMP), etching, and/or the like. Although the principles disclosed herein are not limited to any specific implementation details, in some example embodiments, a value of T10 may be 10 μm or less.

Referring to FIG. 18C, a layer of thermally conductive material 1842 (e.g., diamond such as SCD) may be attached (e.g., bonded) to modified first substrate core layer 1868′ using, for example, a WOW bonding process. Although the principles disclosed herein are not limited to any specific implementation details, in some example embodiments, thermally conductive material 1842 may have a thickness between about 2 μm and 400 μm.

Referring to FIG. 18D, that assembly of first carrier 1841, modified first substrate core layer 1868′, and/or thermally conductive layer 1842 is flipped upside down and attached to another assembly including a second carrier 1947 and a modified semiconductor die layer 1938′ (including an active layer 1940) attached to a second carrier 1947 which may be fabricated, for example, using the embodiments illustrated and described with respect to FIGS. 19A through 19B. For example, thermally conductive layer 1842 may be bonded to modified semiconductor die layer 1938′ using a WOW bonding process.

Referring to FIG. 18E, a die singulation process may be performed to singulate one or more substrate core portions 1875, one or more of which may include a thermally conductive layer 1842 stacked between a substrate core layer 1868′ and a semiconductor die layer 1938′. Singulation may be performed by cutting, dicing, and/or any other suitable process.

Referring to FIG. 18F, singulated substrate core portions 1875 (which may also be referred to as substrate core assemblies) may be removed from second carrier 1947 and used, for example, to fabricate any of the substrate core portions having a thermally conductive layer stacked between a substrate core layer and a semiconductor die layer as disclosed herein.

FIG. 19A and 19B illustrate cross-sectional views of embodiments of a method for fabricating a thinned wafer and one or more wafer assemblies produced thereby, in accordance with example embodiments of the disclosure. The embodiments illustrated in FIG. 19 may be used, for example, to fabricate a modified semiconductor wafer on a carrier for use with the methods illustrated with respect to FIGS. 18 and/or 20.

Referring to FIG. 19A, a wafer (for example, an EIC wafer, a PIC wafer, and/or the like) 1938 having an active layer 1940 may be attached to a carrier 1947 for example, using a WOW process. Wafer 1938 may have an initial thickness of T1. Wafer 1938 may include any type of integrated circuit and/or device functionality including memory (e.g., HBM), cache, IO, energy storage (e.g., ISC), and/or any type of logic such as a general and/or specific purpose integrated circuit (e.g., bridge, FPGA, ASIC, CPU, GPU, NPU, TPU, DPU, and/or the like).

Referring to FIG. 19B, wafer 1938 may be thinned to generate a modified wafer 1938′ having a thickness of T2 using a thinning operation that may include any type of material removal process such as polishing (e.g., CMP), etching, and/or the like. Depending on the implementation details, a thinning operation may reduce a distance T3 between active layer 1940 and a top surface of modified wafer 1938′. Although the principles disclosed herein are not limited to any specific implementation details, in some example embodiments, a value of T2 and/or T3 may be 10 μm or less.

In some embodiments, modified wafer 1938′ may be tested to identify one or more known good dies (KGDs) in modified wafer 1938′.

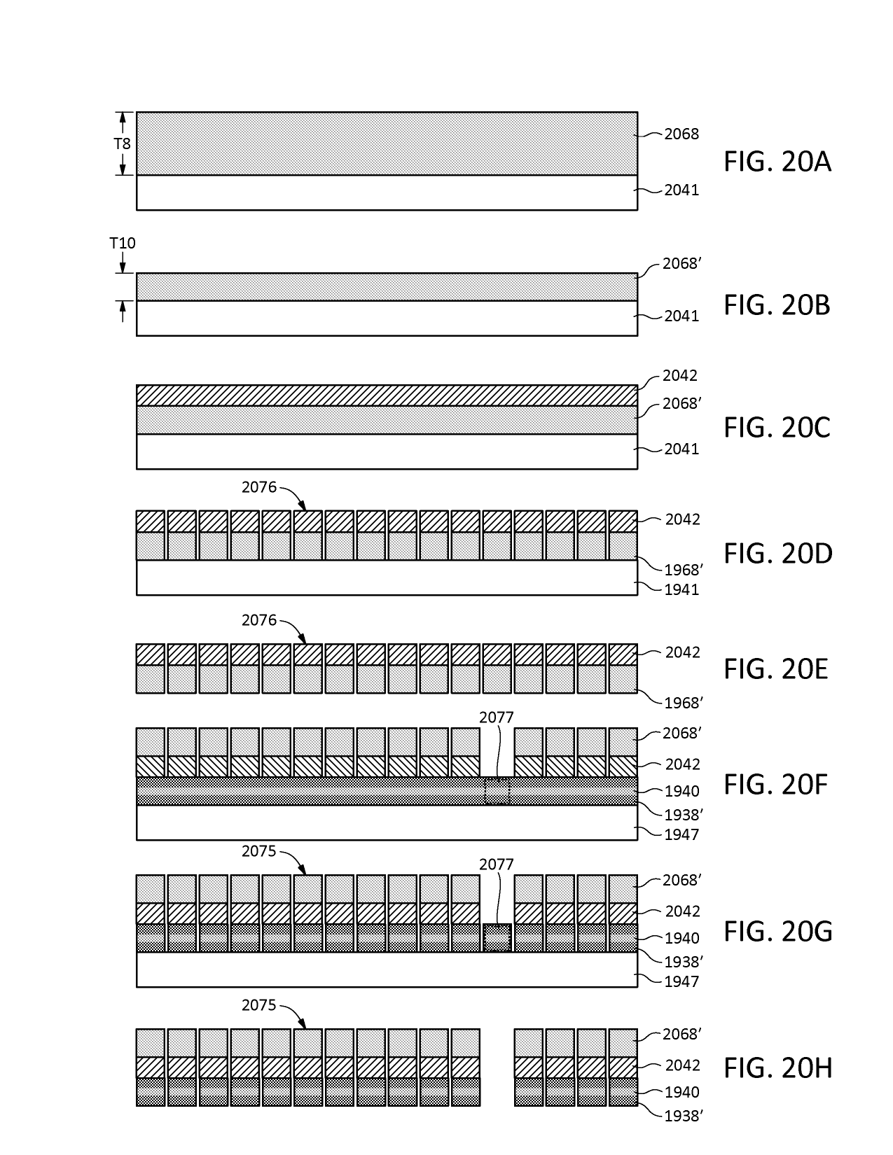

FIGS. 20A through 20H illustrate cross-sectional views of embodiments of operations for a method for fabricating one or more substrate core portions having a substrate core layer attached to a first side of a thermally conductive layer and a semiconductor die layer attached to a second side of the thermally conductive layer, and one or more core portions produced thereby, wherein the semiconductor die layer may be tested for known good dies in accordance with example embodiments of the disclosure. The embodiments illustrated in FIGS. 20A through 20H may include one or more elements and/or use one or more operations and/or processes that may be similar to those illustrated in FIGS. 17A through 17F, FIGS. 18A through 18F, and/or other figures in which similar elements may be indicated by reference numbers ending in, and/or containing, the same digits, letters, and/or the like.

However, in the embodiments illustrated in FIGS. 20A through 20H, a semiconductor die wafer may be tested for known good dies (KGDs) to reduce or eliminate waste that may be caused by attaching singulated assemblies of substrate core and thermally conductive layers to bad dies on a semiconductor die wafer.

Referring to FIG. 20A, a first substrate core layer 2068 (e.g., a semiconductor material, glass material, organic material, and/or the like) may be attached to a first carrier 2041. First substrate core layer 2068 may have an initial thickness of T8.

Referring to FIG. 20B, first substrate core layer 2068 may be thinned to generate a modified first substrate core layer 2068′ having a thickness of T10 using a thinning operation that may include any type of material removal process such as polishing (e.g., CMP), etching, and/or the like. Although the principles disclosed herein are not limited to any specific implementation details, in some example embodiments, a value of T10 may be 10 μm or less.

Referring to FIG. 20C, a layer of thermally conductive material 2042 (e.g., diamond such as SCD) may be attached (e.g., bonded) to modified first substrate core layer 2068′ using, for example, a WOW bonding process. Although the principles disclosed herein are not limited to any specific implementation details, in some example embodiments, thermally conductive material 2042 may have a thickness between about 2 μm and 400 μm.

Referring to FIG. 20D, a singulation process may be performed to singulate one or more partial substrate core portions 2076 having a modified substrate core layer 1968′ and thermally conductive layer 2042. Singulation may be performed by cutting, dicing, and/or any other suitable process.

Referring to FIG. 20E, one or more singulated partial substrate core portions 2076 may be removed from carrier 1941 and used, for example, to fabricate any of the substrate core portions having a substrate core layer attached to a thermally conductive layer disclosed herein.

Referring to FIG. 20F, the sides of singulated partial substrate core portions 2076 having a thermally conductive material 2042 may be attached (e.g., bonded) to KGDs in a modified semiconductor wafer 1938′ which may be attached to a second carrier 1947. In some embodiments, singulated partial substrate core portions 2076 may not be attached to one or more bad dies 2077.

Singulated partial substrate core portions 2076 may be attached to KGDs in modified semiconductor wafer 1938′, for example, using one or more die-on-wafer (DOW) processes. An assembly of modified semiconductor wafer 1938′ and second carrier 1947 may be fabricated, for example, using the embodiments illustrated and described with respect to FIGS. 19A through 19B.

Referring to FIG. 20G, a die singulation process may be performed to singulate one or more KGDs in modified second wafer 1938′ with a lid of thermally conductive material 2042 bonded to a KGD and a substrate core layer 2068′ to form substrate core assemblies 2075. Singulation may be performed by cutting, dicing, and/or any other suitable process.

Referring to FIG. 20H, substrate core assemblies 2075 (which may be referred to as stacks or core stacks) including a thermally conductive layer 2042 stacked between a substrate core layer 2068′ and a KGD of semiconductor wafer 1938′ may be removed from second carrier 1947 and used, for example, to fabricate any of the substrate core structures including a semiconductor die layer disclosed herein.

Depending on the implementation details, the embodiments illustrated and described with respect to FIGS. 20A through 20H may be beneficial, for example, if a size of a wafer of thermally conductive material 2042 does not match a size of a semiconductor wafer 1938′, in which case, a WOW process may be difficult, inefficient, and/or not possible to perform. Additionally, or alternatively, the embodiments illustrated and described with respect to FIGS. 20A through 20H may be beneficial, for example, in situations in which a fabrication process for semiconductor wafer 1938′ may have a relatively low yield, in which case, bonding singulated partial substrate core portions 2076 KGDs (e.g., only to KGDs) may prevent waste of singulated partial substrate core portions 2076, thereby reducing fabrication costs.

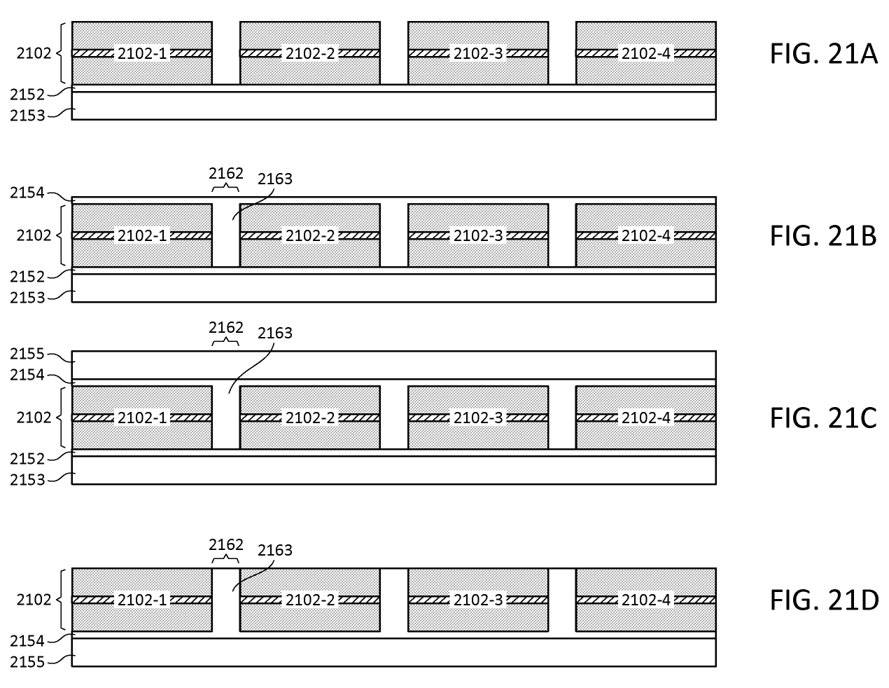

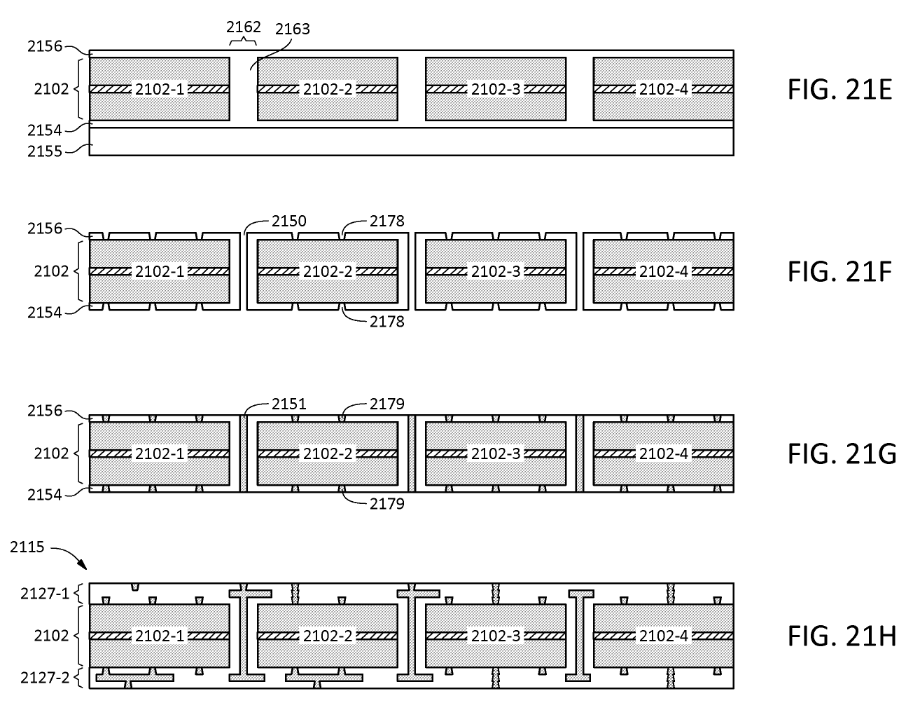

FIGS. 21A through 21H illustrate cross-sectional views of embodiments of a method for fabricating a substrate structure having a substrate core structure with one or more portions having a thermally conductive layer stacked between layers of substrate core materials in accordance with example embodiments of the disclosure. The method illustrated with respect to FIGS. 21A through 21H may be used, for example, to fabricate any of the substrates disclosed herein, and may be performed at a wafer scale, panel scale, and/or the like.

Referring to FIG. 21A, a first side of one or more substrate core portions 2102-1, 2102-2, … may be attached to a first carrier 2153 using a die backside film 2152 to form a substrate core structure 2102.

Referring to FIG. 21B, an RDL dry film, build up film, and/or any other suitable material 2154 may be laminated to a second side of one or more substrate core portions 2102-1, 2102-2, … to form a film (e.g., a thin film) on substrate core structure 2102 and/or used as filler material 2163 to fill one or more gaps 2162 between one or more substrate core portions 2102-1, 2102-2, … of substrate core structure 2102.

Referring to FIG. 21C, a second carrier 2155 may be attached to film 2154 for handling substrate core 2102, for example, so die backside film 2152 may be removed.

Referring to FIG. 21D, substrate core 2102 is flipped vertically compared to the view of FIG. 21C. First carrier 2153 and/or die backside film 2152 may be removed from substrate core 2102 (e.g., removed from substrate core portions 2102-1, 2102-2, … and/or from filler material 2163 in one or more gaps 2162).

Referring to FIG. 21E, a layer 2156 of RDL dry film, build-up film, and/or the like, may be applied to a second side of substrate core 2102 including substrate core portions 2102-1, 2102-2, … and/or over filler material 2163 in one or more gaps 2162.

Referring to FIG. 21F, second carrier 2155 may be removed. One or more vias 2150 (e.g., TOVs if filler material 2163 is implemented with an organic material) may be formed through filler material 2163 in one or more gaps 2162. Additionally, or alternatively, one or more vias 2178 may be formed in one or more of layers 2154 and/or 2156 of RDL dry film, build-up film, and/or the like, to begin the formation of one or more RDLs on one or both sides of substrate core 2102. Vias 2150 and/or 2178 may be formed, for example, using one or more laser drilling, etching, and/or other suitable processes.

Referring to FIG. 21G, one or more vias 2150 through material 2163 in one or more gaps 2162 and/or one or more vias 2178 in one or more of laminate layers 2154 and/or 2156 may be filled with conductive material 2151 and/or 2179, respectively, such as aluminum, copper, conductive polymers, and/or the like.

Referring to FIG. 21H, one or more additional layers of build up film, RDL dry film lamination, and/or the like may be formed on laminate layers 2154 and/or 2156 and patterned and/or filled using lithography, conductive material filling process, and/or the like to form RDLs 2127-1 and/or 2127-2 on one or both sides of substrate core 2102 to form a substrate structure 2115.

In some embodiments, one or more semiconductor die structures and/or substrate core portions may be attached to substrate structure 2115 (e.g., to one or more of RDLs 2127-1 and/or 2127-2 and/or embedded in substrate core 2102) using one or more processes for wafer-level packaging (WLP), panel-level packaging (PLP), soldering processes, and/or the like.

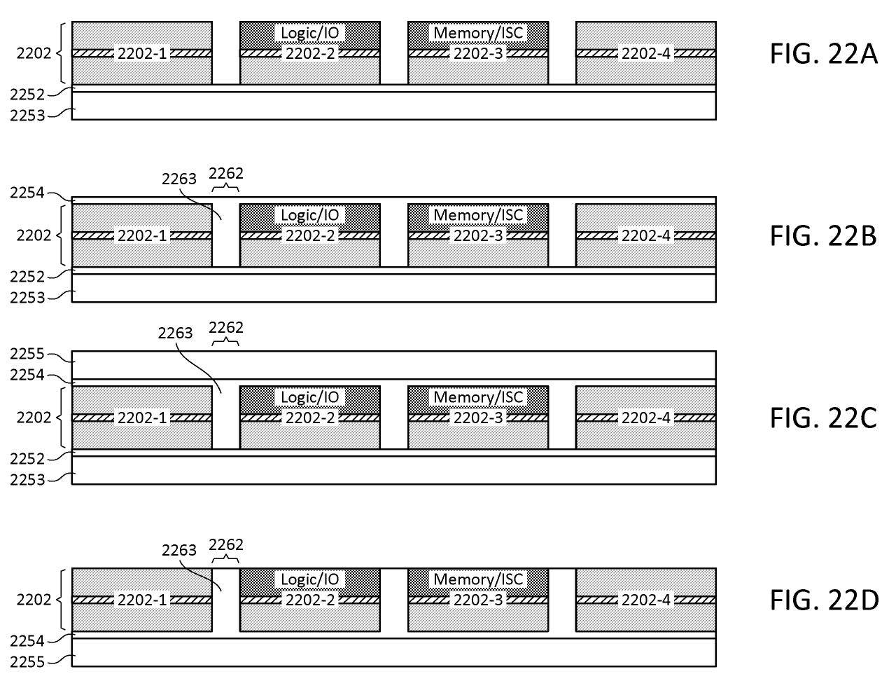

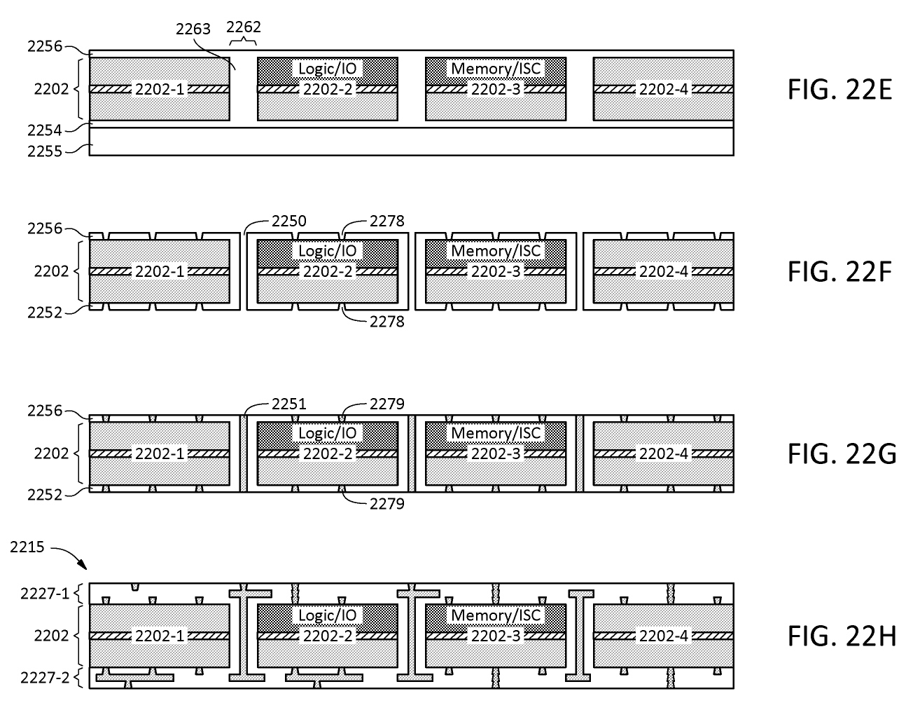

FIGS. 22A through 22H illustrate cross-sectional views of embodiments of a method for fabricating a substrate structure having a substrate core structure with one or more portions having a thermally conductive layer stacked between a layer of substrate core materials and a semiconductor die layer in accordance with example embodiments of the disclosure. The method illustrated with respect to FIGS. 22A through 22H may be used, for example, to fabricate any of the substrates disclosed herein, and may be performed at a wafer scale, panel scale, and/or the like. The embodiments illustrated in FIGS. 22A through 22H may include one or more elements and/or use one or more operations and/or processes that may be similar to those illustrated in FIGS. 21A through 21H and/or other figures in which similar elements may be indicated by reference numbers ending in, and/or containing, the same digits, letters, and/or the like.

However, in the embodiments illustrated in FIGS. 22A through 22H, one or more substrate core portions having a thermally conductive layer stacked between two layers of substrate core material may be replaced with one or more substrate core portions having a thermally conductive layer stacked between a layer of substrate core material and a semiconductor die layer. For purposes of illustration, substrate core portion 2202-2 may be implemented with a semiconductor die layer configured to perform one or more logic and/or IO functions, and substrate core portion 2202-3 may be implemented with a semiconductor die layer configured to perform one or more memory and/or energy storage (e.g., ISC) functions. In other embodiments, however, any numbers and/or combinations of substrate core portions 2202 and/or layers implemented therein, may be used.

The operations and/or structures illustrated and described herein are example operations and/or components shown in a sequence for purposes of illustration. However, in some embodiments, some operations and/or components may be omitted and/or other operations and/or components may be included. Moreover, in some embodiments, the temporal and/or spatial order of the operations and/or components may be varied. Although some components and/or operations may be illustrated as individual components, in some embodiments, some components and/or operations shown separately may be integrated into single components and/or operations, and/or some components and/or operations shown as single components and/or operations may be implemented with multiple components and/or operations.

Some embodiments disclosed above have been described in the context of various implementation details, but the principles of this disclosure are not limited to these or any other specific details. For example, some functionality has been described as being implemented by certain components, but in other embodiments, the functionality may be distributed between different systems and components in different locations and having various interfaces. Certain embodiments have been described as having specific processes, operations, etc., but these terms also encompass embodiments in which a specific process, operation, etc. may be implemented with multiple processes, operations, etc., or in which multiple processes, operations, etc. may be integrated into a single process, step, etc. A reference to a component or element may refer to only a portion of the component or element. For example, a reference to a block may refer to the entire block or one or more subblocks. The use of terms such as “first” and “second” in this disclosure and the claims may only be for purposes of distinguishing the elements they modify and may not indicate any spatial or temporal order unless apparent otherwise from context. In some embodiments, a reference to an element may refer to at least a portion of the element, for example, “based on” may refer to “based at least in part on,” and/or the like. A reference to a first element may not imply the existence of a second element. The principles disclosed herein have independent utility and may be embodied individually, and not every embodiment may utilize every principle. However, the principles may also be embodied in various combinations, some of which may amplify the benefits of the individual principles in a synergistic manner. The various details and embodiments described above may be combined to produce additional embodiments according to the inventive principles of this patent disclosure.

In some embodiments, a portion of an element may refer to less than, or all of, the element. A first portion of an element and a second portion of the element may refer to the same portions of the element. A first portion of an element and a second portion of the element may overlap (e.g., a portion of the first portion may be the same as a portion of the second portion).

Since the inventive principles of this patent disclosure may be modified in arrangement and detail without departing from the inventive concepts, such changes and modifications are considered to fall within the scope of the following claims.

1. An apparatus comprising:
a device comprising:
a first layer having a first thermal conductivity;
a second layer having a second thermal conductivity; and
a third layer having a third thermal conductivity;
wherein:
the first layer comprises a substrate core material;
the third layer comprises a thermally conductive material;
the third thermal conductivity is greater than the first thermal conductivity; and
the third thermal conductivity is greater than the second thermal conductivity.

2. The apparatus of claim 1, wherein the third layer is located between the first layer and the second layer.

3. The apparatus of claim 1, wherein the second layer comprises a substrate core material.

4. The apparatus of claim 1, wherein the second layer comprises a semiconductor die.

5. The apparatus of claim 1, wherein the second layer comprises an energy storage device.

6. The apparatus of claim 1, wherein the second layer comprises a power delivery network.

7. The apparatus of claim 1, further comprising a fourth layer attached to the first layer, wherein the fourth layer comprises a lamination layer.

8. The apparatus of claim 1, further comprising a fourth layer attached to the first layer, wherein the fourth layer comprises a distribution layer.

9. The apparatus of claim 1, wherein the device is a first substrate core structure, the apparatus further comprising a second substrate core structure attached to the first substrate core structure.

10. The apparatus of claim 1, wherein the first layer is bonded to the third layer.

11. An apparatus comprising:
a substrate comprising:
first core portion comprising:
a first layer having a first thermal conductivity, wherein the first layer comprises a substrate core material; and
a second layer having a second thermal conductivity, wherein the second layer comprises a thermally conductive material;
second core portion comprising:
a third layer having a third thermal conductivity, wherein the first layer comprises a substrate core material; and
a fourth layer having a fourth thermal conductivity, wherein the fourth layer comprises a thermally conductive material; and
a lamination layer attached to the first core portion and the second core portion;
wherein the second thermal conductivity is greater than the first thermal conductivity; and
wherein the fourth thermal conductivity is greater than the third thermal conductivity.

12. The apparatus of claim 11, wherein the substrate comprises a via between the first core portion and the second core portion, wherein the via is connected to the lamination layer.

13. The apparatus of claim 11, wherein the lamination layer comprises a via connected to the first core portion.

14. The apparatus of claim 11, further comprising a semiconductor die structure attached to the lamination layer.

15. The apparatus of claim 11, wherein:
the first layer is attached to a first side of the second layer;
the first core portion further comprises a fifth layer attached to a second side of the second layer; and
the fifth layer comprises a substrate core material.

16. The apparatus of claim 11, further comprising:
a first semiconductor die structure attached to the lamination layer; and
a second semiconductor die structure attached to the lamination layer;
wherein the first core portion further comprises a semiconductor die layer attached to the second layer and electrically connected to the first semiconductor die structure and the second semiconductor die structure.

17. The apparatus of claim 11, wherein the substrate is a first substrate, the apparatus further comprising a second substrate attached to the first substrate.

18. A method comprising:
performing, on a substrate core layer, a thinning operation, thereby forming a modified substrate core layer; and
attaching, to the modified substrate core layer, a thermally conductive layer, thereby forming a substrate core structure;
wherein the thermally conductive layer has a thermal conductivity that is greater than a thermal conductivity of the modified substrate core layer.

19. The method of claim 18, further comprising attaching, to the modified substrate core layer, a lamination layer.

20. The method of claim 18, wherein the modified substrate core layer is attached to a first side of the thermally conductive layer, the method further comprising attaching, to a second side of the thermally conductive layer, a semiconductor die layer.
